(19) United States
(12) Patent Application Publication
(10) Pub. No.: US 2025/0107424 A1
(43) Pub. Date: Mar. 27, 2025

(54) APPARATUS AND METHOD FOR MANUFACTURING DISPLAY DEVICE

(71) Applicant: Samsung Display Co., Ltd., Yongin-si (KR)

(72) Inventors: Hyoungjun Ahn, Yongin-si (KR); Taehoon Park, Yongin-si (KR); Kyoungjin Seo, Yongin-si (KR); Jinwook Lee, Yongin-si (KR); Byunggyu Chae, Yongin-si (KR); Donghyuk Choi, Yongin-si (KR); Sangjin Han, Yongin-si (KR)

(21) Appl. No.: 18/823,514

(22) Filed: Sep. 3, 2024

(30) Foreign Application Priority Data
Sep. 22, 2023 (KR) 10-2023-0127367
Dec. 29, 2023 (KR) 10-2023-0197607

(51) Int. Cl. H10K 71/60; H01L 21/67; H01L 21/68; H01L 21/683; H10K 59/12

(52) U.S. Cl. CPC H10K 71/60; H01L 21/67092; H01L 21/681; H01L 21/6831; H10K 59/1201

(57) ABSTRACT

Disclosed are an apparatus for and method of manufacturing a display device. The apparatus for manufacturing a display device includes a seating portion on which a substrate having a dummy layer thereon is seated, support portions on the seating portion to support the substrate, a measurement portion facing the seating portion, and configured to measure a thickness of the dummy layer, wherein the seating portion is configured to move linearly so that the measurement portion and the dummy layer are positioned at corresponding positions based on a result of detection by the measurement portion.

### CROSS-REFERENCE TO RELATED APPLICATIONS

The present application claims priority to, and the benefit of, Korean Patent Application Nos. 10-2023-0127367, filed on Sep. 22, 2023, and 10-2023-0197607, filed on Dec. 29, 2023, in the Korean Intellectual Property Office, the entire disclosures of which are incorporated herein by reference.

### BACKGROUND

### 1. Field

One or more embodiments relate to an apparatus and a method for manufacturing a display device.

### 2. Description of the Related Art

Mobile electronic devices have been widely used. In addition to compact electronic devices, such as mobile phones, tablet personal computers (PCs) have recently been widely used as mobile electronic devices.

To support various functions, mobile electronic devices include display devices to provide visual information, such as images or videos, to users. In recent years, as other components for driving display devices have been reduced in size, the proportion occupied by display devices in electronic devices has gradually increased, and also, structures that may be bent to a corresponding angle from a flat state have been developed.

When manufacturing such a display device, various layers are formed, and a thickness of at least one of the various layers determines the performance of the display device.

### SUMMARY

In general, when forming at least one layer of a display device, it is suitable to form the at least one layer to a thickness equal to or similar to a corresponding (e.g., preset) thickness. To this end, various methods are used, but the thickness of the at least one layer may be different from the corresponding (e.g., preset) thickness. In this case, the manufactured display device may not emit light of a suitable wavelength to the outside, or the performance of the display device may be deteriorated. One or more embodiments include an apparatus and method for manufacturing a display device, in which a thickness of at least one layer is measured and compensated for, so that the display device of uniform quality may be manufactured.

Additional aspects will be set forth in part in the description that follows and, in part, will be apparent from the description, or may be learned by practice of the embodiments of the disclosure.

According to one or more embodiments, an apparatus for manufacturing a display device includes a seating portion on which a substrate having a dummy layer thereon is seated, support portions on the seating portion to support the substrate, a measurement portion facing the seating portion, and configured to measure a thickness of the dummy layer, wherein the seating portion is configured to move linearly so that the measurement portion and the dummy layer are positioned at corresponding positions based on a result of detection by the measurement portion.

The apparatus may further include a driving portion connected to the seating portion, and configured to move the seating portion linearly.

The apparatus may further include a detection portion configured to detect a position of the seating portion and a position of the substrate.

The seating portion may be further configured to move the substrate linearly based on a result of detection by the detection portion.

The support portions may be at different respective heights.

The apparatus may further include a movement driving portion configured to move a detection portion or the measurement portion therein.

The apparatus may further include a processing portion configured to deposit a layer on the substrate, and a path unit connected to the processing portion, and configured to determine a movement path of the substrate, wherein the seating portion, the support portions, and the measurement portion are arranged in the processing portion or in the path unit.

The processing portion may include a first processing portion and a second processing portion configured to deposit respective layers on the substrate, wherein a thickness of a layer on the substrate is configured to be adjusted in the first processing portion or in the second processing portion based on a measurement of the layer on the substrate in the first processing portion.

The apparatus may further include a substrate pressing portion facing the support portions or the seating portion, and configured to keep at least a portion of the substrate flat.

The measurement portion may be further configured to irradiate a signal in a direction perpendicular to one surface of the dummy layer.

According to one or more embodiments, a method of manufacturing a display device includes moving a substrate on a seating portion to a position, separating the substrate from a support portion, moving the support portion to an initial position, seating the substrate on the support portion, moving the substrate to the position, and moving the support portion so that a dummy layer on the substrate corresponds to a dummy position.

The method may further include detecting the position of the substrate and a position of the seating portion.

The method may further include measuring a thickness of the dummy layer.

The thickness of the dummy layer may be measured during transferring of the substrate.

The thickness of the dummy layer may be measured at a space of the substrate having a same layer as the dummy layer.

The method may further include measuring a position of the dummy layer.

The method may further include comparing the position of the dummy layer with the dummy position.

The method may further include supporting different portions of the substrate at different respective heights.

The method may further include keeping the substrate flat.

The method may further include keeping a portion of the substrate flat by applying a pressure to an end of the substrate adjacent to the dummy layer, the dummy layer being at the portion of the substrate.

These and/or other aspects will become apparent and more readily appreciated from the following detailed description of the embodiments, the accompanying drawings, and claims.

These aspects may be practiced by using a system, a method, a computer program, or any combinations thereof.

### BRIEF DESCRIPTION OF THE DRAWINGS

The above and other aspects of embodiments of the disclosure will be more apparent from the following description taken in conjunction with the accompanying drawings, in which:

FIG. 1 is a plan view schematically illustrating an apparatus for manufacturing a display device, according to one or more embodiments;

FIG. 2 is a cross-sectional view schematically illustrating a first connection portion shown in FIG. 1;

FIG. 3 is a perspective view schematically illustrating a first seating portion, a first support portion, and a first driving portion that are shown in FIG. 2;

FIGS. 4A to 4G are partial perspective views schematically illustrating part of an operation of the apparatus for manufacturing a display device, shown in FIG. 1;

FIG. 5 is a front view schematically illustrating part of the first support portion shown in FIG. 3;

FIG. 6A is a cross-sectional view schematically illustrating a third processing portion of an apparatus for manufacturing a display device, according to one or more other embodiments;

FIG. 6B is a plan view schematically illustrating a rotation portion and a display substrate that are shown in FIG. 6A;

FIG. 7 is a front view schematically illustrating a portion of an apparatus for manufacturing a display device, according to one or more other embodiments;

FIG. 8 is a front view schematically illustrating a portion of an apparatus for manufacturing a display device, according to one or more other embodiments;

FIG. 9 is a front view illustrating a portion of an apparatus for manufacturing a display device, according to one or more other embodiments;

FIG. 10 is a plan view schematically illustrating a display device according to one or more embodiments;

FIG. 11 is a cross-sectional view schematically illustrating a cross-section taken along the line XI-XI′ in FIG. 10;

FIG. 12 is a cross-sectional view schematically illustrating an organic light-emitting diode of the display device in FIG. 11;

FIG. 13 is a cross-sectional view schematically illustrating the organic light-emitting diode of the display device in FIG. 11;

FIG. 14 is a cross-sectional view schematically illustrating the organic light-emitting diode of the display device in FIG. 11; and

FIG. 15 is a cross-sectional view schematically illustrating the organic light-emitting diode of the display device in FIG. 11.

### DETAILED DESCRIPTION

Reference will now be made in detail to embodiments, examples of which are illustrated in the accompanying drawings, wherein like reference numerals refer to like elements throughout. In this regard, the present embodiments may have different forms and should not be construed as being limited to the descriptions set forth herein. Accordingly, the embodiments are merely described below, by referring to the figures, to explain aspects of the present description. As used herein, the term “and/or” includes any and all combinations of one or more of the associated listed items. Throughout the disclosure, the expression “at least one of a, b, or c” indicates only a, only b, only c, both a and b, both a and c, both b and c, all of a, b, and c, or variations thereof.

As the disclosure allows for various changes and numerous embodiments, embodiments will be illustrated in the drawings and described in detail in the written description. Hereinafter, aspects of the disclosure and a method for accomplishing them will be described more fully with reference to the accompanying drawings, in which embodiments of the disclosure are shown. This disclosure may, however, be embodied in many different forms and should not be construed as limited to the embodiments set forth herein.

Hereinafter, embodiments will be described with reference to the accompanying drawings, wherein like reference numerals refer to like elements throughout and a repeated description thereof is omitted.

In one or more embodiments below, terms, such as “first” and “second” are used herein merely to describe a variety of elements, but the elements are not limited by the terms. Such terms are used only for the purpose of distinguishing one element from another element.

In one or more embodiments below, an expression used in the singular encompasses the expression of the plural, unless it has a clearly different meaning in the context.

In one or more embodiments below, terms, such as “include” or “comprise” may be construed to denote a characteristic or element, or a combination thereof, but may not be construed to exclude the existence of or a possibility of addition of one or more other characteristics, elements, or combinations thereof.

Spatially relative terms, such as “beneath,” “below,” “lower,” “lower side,” “under,” “above,” “upper,” “upper side,” and the like, may be used herein for ease of explanation to describe one element or feature's relationship to another element(s) or feature(s) as illustrated in the figures. It will be understood that the spatially relative terms are intended to encompass different orientations of the device in use or in operation, in addition to the orientation depicted in the figures. For example, if the device in the figures is turned over, elements described as “below,” “beneath,” “or “under” other elements or features would then be oriented “above” the other elements or features. Thus, the example terms “below” and “under” can encompass both an orientation of above and below. The device may be otherwise oriented (e.g., rotated 90 degrees or at other orientations) and the spatially relative descriptors used herein should be interpreted accordingly. Similarly, when a first part is described as being arranged “on” a second part, this indicates that the first part is arranged at an upper side or a lower side of the second part without the limitation to the upper side thereof on the basis of the gravity direction.

Further, the phrase “in a plan view” means when an object portion is viewed from above, and the phrase “in a schematic cross-sectional view” means when a schematic cross-section taken by vertically cutting an object portion is viewed from the side. The terms “overlap” or “overlapped” mean that a first object may be above or below or to a side of a second object, and vice versa. Additionally, the term “overlap” may include stack, face or facing, extending over, covering, or partly covering or any other suitable term as would be appreciated and understood by those of ordinary skill in the art. The expression “not overlap” may include meaning, such as “apart from” or “set aside from” or “offset from” and any other suitable equivalents as would be appreciated and understood by those of ordinary skill in the art. The terms “face” and “facing” may mean that a first object may directly or indirectly oppose a second object. In a case in which a third object intervenes between a first and second object, the first and second objects may be understood as being indirectly opposed to one another, although still facing each other.

It will be understood that when an element, layer, region, or component is referred to as being “formed on,” “on,” “connected to,” or “(operatively or communicatively) coupled to” another element, layer, region, or component, it can be directly formed on, on, connected to, or coupled to the other element, layer, region, or component, or indirectly formed on, on, connected to, or coupled to the other element, layer, region, or component such that one or more intervening elements, layers, regions, or components may be present. In addition, this may collectively mean a direct or indirect coupling or connection and an integral or non-integral coupling or connection. For example, when a layer, region, or component is referred to as being “electrically connected” or “electrically coupled” to another layer, region, or component, it can be directly electrically connected or coupled to the other layer, region, and/or component or one or more intervening layers, regions, or components may be present. The one or more intervening components may include a switch, a resistor, a capacitor, and/or the like. In describing embodiments, an expression of connection indicates electrical connection unless explicitly described to be direct connection, and “directly connected/directly coupled,” or “directly on,” refers to one component directly connecting or coupling another component, or being on another component, without an intermediate component.

In addition, in the present specification, when a portion of a layer, a film, an area, a plate, or the like is formed on another portion, a forming direction is not limited to an upper direction but includes forming the portion on a side surface or in a lower direction. On the contrary, when a portion of a layer, a film, an area, a plate, or the like is formed “under” another portion, this includes not only a case where the portion is “directly beneath” another portion but also a case where there is further another portion between the portion and another portion. Meanwhile, other expressions describing relationships between components, such as “between,” “immediately between” or “adjacent to” and “directly adjacent to,” may be construed similarly. It will be understood that when an element or layer is referred to as being “between” two elements or layers, it can be the only element or layer between the two elements or layers, or one or more intervening elements or layers may also be present.

Sizes of elements in the drawings may be exaggerated or reduced for convenience of explanation. For example, because sizes and thicknesses of elements in the drawings are arbitrarily illustrated for convenience of explanation, the disclosure is not limited thereto.

In the following embodiments, the X-axis, the Y-axis, and the Z-axis are not limited to three axes of the rectangular coordinate system, and may be interpreted in a broader sense. For example, the X-axis, the Y-axis, and the Z-axis may be perpendicular to one another, or may represent different directions that are not perpendicular to one another.

When one or more embodiments may be implemented differently, a process order may be performed differently from the described order. For example, two consecutively described processes may be performed substantially at the same time or performed in an order opposite to the described order.

In some embodiments well-known structures and devices may be described in the accompanying drawings in relation to one or more functional blocks (e.g., block diagrams), units, and/or modules to avoid unnecessarily obscuring various embodiments. Those skilled in the art will understand that such block, unit, and/or module are/is physically implemented by a logic circuit, an individual component, a microprocessor, a hard wire circuit, a memory element, a line connection, and other electronic circuits. This may be formed using a semiconductor-based manufacturing technique or other manufacturing techniques. The block, unit, and/or module implemented by a microprocessor or other similar hardware may be programmed and controlled using software to perform various functions discussed herein, optionally may be driven by firmware and/or software. In addition, each block, unit, and/or module may be implemented by dedicated hardware, or a combination of dedicated hardware that performs some functions and a processor (for example, one or more programmed microprocessors and related circuits) that performs a function different from those of the dedicated hardware. In addition, in some embodiments, the block, unit, and/or module may be physically separated into two or more interact individual blocks, units, and/or modules without departing from the scope of the present disclosure. In addition, in some embodiments, the block, unit and/or module may be physically combined into more complex blocks, units, and/or modules without departing from the scope of the present disclosure.

Unless otherwise defined, all terms (including technical and scientific terms) used herein have the same meaning as commonly understood by one of ordinary skill in the art to which the present disclosure belongs. It will be further understood that terms, such as those defined in commonly used dictionaries, should be interpreted as having a meaning that is consistent with their meaning in the context of the relevant art and/or the present specification, and should not be interpreted in an idealized or overly formal sense, unless expressly so defined herein.

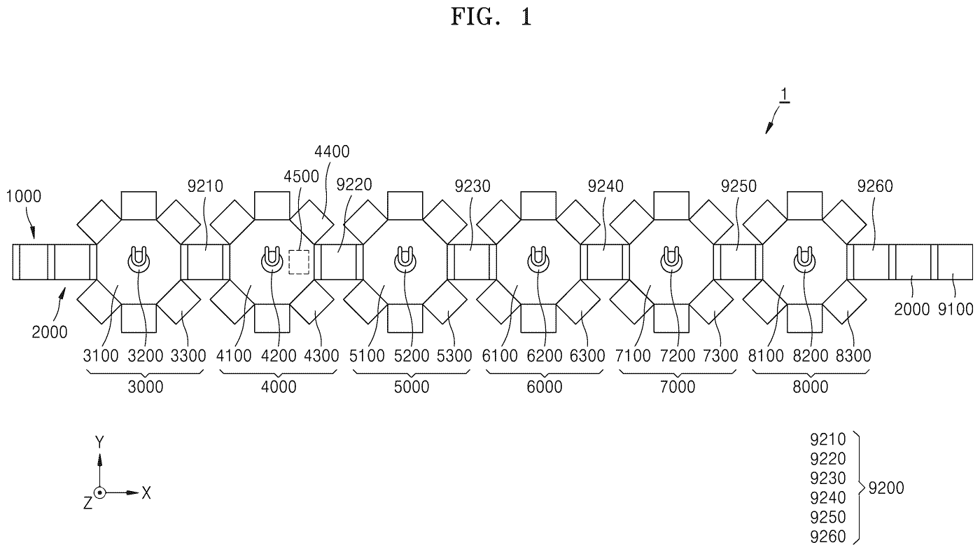

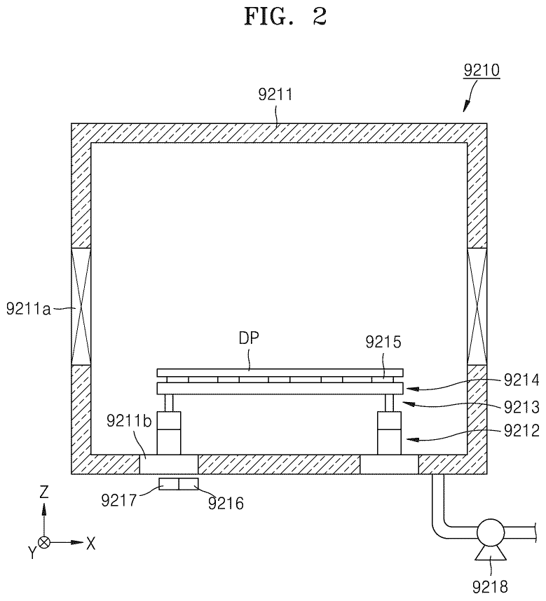

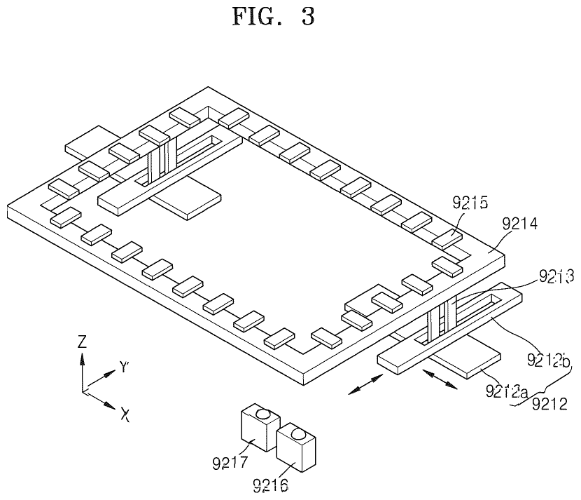

FIG. 1 is a plan view schematically illustrating an apparatus 1 for manufacturing a display device, according to one or more embodiments. FIG. 2 is a cross-sectional view schematically illustrating a first connection portion 9210 shown in FIG. 1. FIG. 3 is a perspective view schematically illustrating a first seating portion 9214, a first support portion 9215, and a first driving portion 9212 that are shown in FIG. 2.

Referring to FIGS. 1 to 3, the apparatus 1 for manufacturing a display device may include a loading portion 1000, a flip portion 2000, at least one cluster, an unloading portion 9100, and the connection portion(s) 9200.

A display substrate DP may be introduced into the loading portion 1000 from the outside. In one or more embodiments, the display substrate DP may have at least one layer located on a substrate, which is described below. In one or more embodiments, the loading portion 1000 may have a separate robot arm to move the display substrate DP to the flip portion 2000.

The flip portion 2000 may invert the display substrate DP transferred from the loading portion 1000. For example, the flip portion 2000 may invert the display substrate DP so that one surface of the display substrate DP on which a layer is formed is viewed from top to bottom, the layer being formed when a process is performed in at least one cluster.

The at least one cluster may temporarily accommodate the display substrate DP, or may form a single layer on the display substrate DP. In this case, the at least one cluster may include a transfer chamber, which is a path unit that is connected to the connection portion 9200, which is a path unit, to temporarily store and transfer the display substrate DP, and may include a processing portion that is connected to the transfer chamber to form a single layer on the display substrate DP. In one or more other embodiments, the at least one cluster may also include a thickness measurement portion for measuring a thickness of a layer formed in the processing portion. In this case, in one or more embodiments, the thickness measurement portion may be provided in at least one of a plurality of clusters. The thickness measurement portion may be arranged between transfer chambers of the clusters to connect the connection portion 9200 and the transfer chamber to each other. Hereinbelow, for convenience of description, it is mainly described a case in which the at least one cluster includes a plurality of clusters, and the thickness measurement portion is provided in a second cluster 4000.

In one or more embodiments, the plurality of clusters may include a first cluster 3000, the second cluster 4000, a third cluster 5000, a fourth cluster 6000, a fifth cluster 7000, and a sixth cluster 8000, which may be respectively connected to one another.

The first cluster 3000 may include a first transfer chamber 3100, which is connected to the flip portion 2000 and in which a first robot arm 3200 is arranged, and a first processing portion 3300, which is connected to the first transfer chamber 3100, to form a first layer on the display substrate DP. In this case, the first layer may be a first functional layer described below. In this case, the first functional layer may include a plurality of layers including different materials from each other.

The second cluster 4000 may be connected to the first cluster 3000 through the connection portion 9200. In this case, the second cluster 4000 may include a second transfer chamber 4100, which is connected to the connection portion 9200 and in which a second robot arm 4200 is arranged, and a second processing portion 4300 connected to the second transfer chamber 4100 to form a second layer on the display substrate DP. In addition, the second cluster 4000 may include a second thickness measurement portion 4400, which is connected to the second transfer chamber 4100, and in which a second thickness measurement unit described below is arranged.

The third cluster 5000 may be connected to the second cluster 4000 through the connection portion 9200. In this case, the third cluster 5000 may include a third transfer chamber 5100, which is connected to the connection portion 9200 and in which a third robot arm 5200 is arranged, and a third processing portion 5300 connected to the third transfer chamber 5100 to form a third layer on the display substrate DP.

The fourth cluster 6000 may be connected to the third cluster 5000 through the connection portion 9200. In this case, the fourth cluster 6000 may include a fourth transfer chamber 6100, which is connected to the connection portion 9200 and in which a fourth robot arm 6200 is arranged, and a fourth processing portion 6300 connected to the fourth transfer chamber 6100 to form a fourth layer on the display substrate DP. In this case, the fourth processing portion 6300 may include a plurality of fourth processing portions 6330, and the plurality of fourth processing portion 6300 may form different layers from each other. For example, each fourth processing portion 6300 may form an organic emission layer, and the plurality of fourth processing portions 6300 may form organic emission layers that include different materials from each other. For example, each fourth processing portion 6300 may form a green, red, or blue organic emission layer on the third layer.

The fifth cluster 7000 may be connected to the fourth cluster 6000 through the connection portion 9200. In this case, the fifth cluster 7000 may include a fifth transfer chamber 7100, which is connected to the connection portion 9200 and in which a fifth robot arm 7200 is arranged, and a fifth processing portion 7300 connected to the fifth transfer chamber 7100 to form a fifth layer on the display substrate DP.

The sixth cluster 8000 may be connected to the fifth cluster 7000 through the connection portion 9200. In this case, the sixth cluster 8000 may include a sixth transfer chamber 8100, which is connected to the connection portion 9200 and in which a sixth robot arm 8200 is arranged, and a sixth processing portion 8300 connected to the sixth transfer chamber 8100 to form a sixth layer on the display substrate DP. In this case, the sixth processing portion 8300 may include a plurality of sixth processing portions 8300, and the plurality of sixth processing portions 8300 may form different layers from each other. For example, one of the plurality of sixth processing portions 8300 may form a sixth-1 layer, another one of the plurality of sixth processing portions 8300 may form a sixth-2 layer, another one of the plurality of sixth processing portions 8300 may form a sixth-3 layer, and another one of the plurality of sixth processing portions 8300 may form a sixth-4 layer. In this case, the sixth-1 layer, the sixth-2 layer, the sixth-3 layer, and the sixth-4 layer may be sequentially stacked on the fifth layer. In one or more other embodiments, the sixth cluster 8000 may include a plurality of sixth clusters 8000 connected to each other. In this case, the plurality of sixth clusters 8000 may form the sixth-1 layer, the sixth-2 layer, the sixth-3 layer, and the sixth-4 layer. In this case, the plurality of sixth clusters 8000 may be arranged in a row.

The unloading portion 9100 may be connected to at least one cluster and may carry out the display substrate DP of which a process has been completed to the outside or deliver the display substrate DP to another apparatus for manufacturing a display device.

The connection portion 9200 may be a path unit, and the connection portion 9200 may be arranged between the flip portion 2000 and the first cluster 3000, between adjacent clusters from among the first cluster 3000 to the sixth cluster 8000, and between the sixth cluster 8000 and the unloading portion 9100. The connection portion 9200 may not only connect adjacent configurations to each other, but also may transfer the display substrate DP between the adjacent configurations. For example, the connection portion 9200 may include a first connection portion 9210, a second connection portion 9220, a third connection portion 9230, a fourth connection portion 9240, a fifth connection portion 9250, and a sixth connection portion 9260. In this case, the first connection portion 9210 may be arranged between the first cluster 3000 and the second cluster 4000, the second connection portion 9220 may be arranged between the second cluster 4000 and the third cluster 5000, the third connection portion 9230 may connect the third cluster 5000 and the fourth cluster 6000 to each other, the fourth connection portion 9240 may be arranged between the fourth cluster 6000 and the fifth cluster 7000, the fifth connection portion 9250 may be arranged between the fifth cluster 7000 and the sixth cluster 8000, and the sixth connection portion 9260 may connect the sixth cluster 8000 and the unloading portion 9100 to each other. In one or more other embodiments, the sixth connection portion 9260 may connect the sixth cluster 8000 and the flip portion 2000 to each other, and the flip portion 2000 may be connected to the unloading portion 9100.

The apparatus 1 for manufacturing a display device may include a thickness measurement unit that measures a thickness of at least one layer from among various layers stacked on the display substrate DP. In this case, the thickness measurement unit may form each layer, and may be arranged on a path along which the display substrate DP on which these layers are formed moves. In addition, the thickness measurement unit may include a plurality of thickness measurement units, and each of the thickness measurement units may measure at least one of a thickness of each layer stacked on the display substrate DP in the apparatus 1 for manufacturing a display device, or a thickness of each dummy layer formed concurrently or substantially simultaneously with each layer. In other words, the plurality of thickness measurement units may include a first thickness measurement unit that measures at least one of a thickness of a first layer or a thickness of a first dummy layer, a second thickness measurement unit that measures at least one of a thickness of a second layer or a thickness of a second dummy layer, a third thickness measurement unit that measures at least one of a thickness of a third layer or a thickness of a third dummy layer, a fourth thickness measurement unit that measures at least one of a thickness of a fourth layer or a thickness of a fourth dummy layer, a fifth thickness measurement unit that measures at least one of a thickness of a fifth layer or a thickness of a fifth dummy layer, and/or a sixth thickness measurement unit that measures at least one of a thickness of a sixth layer or a thickness of a sixth dummy layer.

In this case, each thickness measurement unit may measure at least one of a thickness of a layer formed in one cluster or a thickness of a dummy layer, and may be arranged in at least one of a transfer chamber, a processing portion, a thickness measurement portion of the one cluster, or the connection portion 9200 connected to this cluster. For example, the first thickness measurement unit may be arranged in at least one of the first transfer chamber 3100, the first processing portion 3300, or the first connection portion 9210. The second thickness measurement unit may be arranged in at least one of the second transfer chamber 4100, the second processing portion 4300, the second thickness measurement portion 4400, or the second connection portion 9220. The third thickness measurement unit may be arranged in at least one of the third transfer chamber 5100, the third processing portion 5300, or the third connection portion 9230. The fourth thickness measurement unit may be arranged in at least one of the fourth transfer chamber 6100, the fourth processing portion 6300, or the fourth connection portion 9240. The fifth thickness measurement unit may be arranged in at least one of the fifth transfer chamber 7100, the fifth processing portion 7300, or the fifth connection portion 9250. The sixth thickness measurement unit may be arranged in at least one of the sixth transfer chamber 8100, the sixth processing portion 8300, or the sixth connection portion 9260. In this case, when forming a plurality of different layers in one cluster, at least one of a thickness of a layer or a thickness of a dummy layer corresponding to that layer may be measured only in one of a transfer chamber or a processing portion of the corresponding cluster. For example, in the third cluster 5000, the third thickness measurement unit may be arranged in at least one of the third transfer chamber 5100 or the third processing portion 5300 to measure at least one of a thickness of the third layer or a thickness of the third dummy layer. In the sixth cluster 8000, the sixth thickness measurement unit may be arranged only in at least one of the sixth transfer chamber 8100 or the sixth processing portion 8300 to measure at least one of a thickness of the sixty layer or a thickness of the sixth dummy layer. The first to six thickness measurement units may be formed similarly to each other, and may be arranged in similar positions. For convenience of description, the first thickness measurement unit is described below in detail.

Although it is described above that the apparatus 1 for manufacturing a display device has only the second thickness measurement portion 4400, one or more embodiments are not limited thereto. In other words, the apparatus 1 for manufacturing a display device may include at least one of a first thickness measurement portion connected to the first transfer chamber 3100, a second thickness measurement portion 4400 connected to the second transfer chamber 4100, a third thickness measurement portion connected to the third transfer chamber 5100, a fourth thickness measurement portion connected to the fourth transfer chamber 6100, a fifth thickness measurement portion connected to the fifth transfer chamber 7100, or a sixth thickness measurement portion connected to the sixth transfer chamber 8100. In addition, each of the first thickness measurement portion, the second thickness measurement portion 4400, the third thickness measurement portion, the fourth thickness measurement portion, the fifth thickness measurement portion, and the sixth thickness measurement portion described above may have a similar form to the first connection portion 9210 described below.

Referring to FIGS. 2 and 3, the first cluster 3000 or the first connection portion 9210 may include a first thickness detection unit for detecting a thickness of a first layer. In other words, the first thickness detection unit may be arranged in the first transfer chamber 3100, the first processing portion 3300, or the first connection portion 9210. For convenience of description, a case in which the first thickness detection unit is arranged in the first connection portion 9210 is mainly described below in detail.

The first connection portion 9210 may include a first connection chamber 9211 and the first thickness detection unit. In this case, the first thickness detection unit may include a first driving portion 9212, a first linear movement portion 9213, a first seating portion 9214, a first support portion 9215, a first detection portion 9216, and a first measurement portion 9217.

The first connection chamber 9211 may connect the first transfer chamber 3100 and the second transfer chamber 4100 to each other. In this case, a first pressure adjust portion 9218 capable of adjusting pressure inside the first connection chamber 9211 may be connected to the first connection chamber 9211. The first pressure adjust portion 9218 may include a first pipe connected to the first connection chamber 9211 and a first pump located on the first pipe. The first connection chamber 9211 described above may have one open area, and a separate first opening/closing portion 9211a, such as a gate valve for opening and closing an open area may be arranged in the one open area. In addition, a first transmission window 9211b of which the inside may be transmitted from the outside may be provided on an outer surface of the first connection chamber 9211. In this case, the first transmission window 9211b may include a transparent material. In this case, at least one of the first detection portion 9216 or the first measurement portion 9217 may be arranged inside the first connection chamber 9211 or outside the first connection chamber 9211.

The first driving portion 9212 may be arranged inside the first connection chamber 9211, and may allow the first seating portion 9214 to linearly move in at least one direction from among a first direction (e.g., the X direction in FIG. 2) or a second direction (e.g., the Y direction in FIG. 2). In this case, the first driving portion 9212 may include a first-1 driving portion 9212a and a first-2 driving portion 9212b, which are connected to each other. One of the first-1 driving portion 9212a and the first-2 driving portion 9212b may be seated on the other one of the first-1 driving portion 9212a and the first-2 driving portion 9212b. In addition, the first linear movement portion 9213 may be seated on the one of the first-1 driving portion 9212a and the first-2 driving portion 9212b. For convenience of description, a case in which the first-2 driving portion 9212b is seated on the first-1 driving portion 9212a, and the first linear movement portion 9213 is seated on the first-2 driving portion 9212b is mainly described below in detail.

The first-2 driving portion 9212b may be seated on the first-1 driving portion 9212a, and may linearly move on the first-1 driving portion 9212a according to an operation of the first-1 driving portion 9212a. In addition, the first linear movement portion 9213 may be located on the first-2 driving portion 9212b, and may linearly move on the first-2 driving portion 9212b according to an operation of the first-2 driving portion 9212b.

The first-1 driving portion 9212a and the first-2 driving portion 9212b described above may be formed in various shapes. In this case, because the first-1 driving portion 9212a and the first-2 driving portion 9212b have similar shapes, the first-1 driving portion 9212a is mainly described below in detail, for convenience of description.

The first-1 driving portion 9212a may have various shapes. For example, the first-1 driving portion 9212a may include a cylinder, a movement block connected to the cylinder to move according to an operation of the cylinder, and a rail along which the movement block is arranged and which guides movement of the movement block. In one or more other embodiments, the first-1 driving portion 9212a may include a motor, a ball screw connected to the motor to operate, and a movement block that linearly moves according to rotation of the ball screw. In this case, the first-1 driving portion 9212a may further include a separate rail that guides movement of the movement block. In one or more other embodiments, the first-1 driving portion 9212a may include a linear motor. In this case, the first-1 driving portion 9212a is not limited thereto, and may include any device and structure that allows the first-2 driving portion 9212b to linearly move in a state in which the first-2 driving portion 9212b is mounted.

The first linear movement portion 9213 may protrude toward the first driving portion 9212 from the first seating portion 9214, and may connect the first seating portion 9214 and the first driving portion 9212 to each other. For example, the first linear movement portion 9213 may be connected to a linearly moving portion of the first-2 driving portion 9212b. In this case, one pair of first linear movement portions 9213 and one pair of first driving portions 9212 may be provided, and the two pairs may be arranged to be symmetrical to each other with respect to the first seating portion 9214.

The first seating portion 9214 may be connected to the first linear movement portion 9213. The first seating portion 9214 may have/define an opening area in a central portion thereof. Through this opening area, a portion of the display substrate DP on the first seating portion 9214 may be exposed to the outside.

The first support portion 9215 may be located on the first seating portion 9214, and may support an edge of the display substrate DP. In this case, the first support portion 9215 may include a plurality of first support portions 9215, and the plurality of first support portions 9215 may be located spaced apart from each other on the first seating portion 9214. In addition, the plurality of first support portions 9215 may support at least two edges of the display substrate DP. In addition, each of the first support portions 9215 may support a portion of the display substrate DP with no layers formed thereon.

The plurality of first support portions 9215 may be arranged at different heights from each other on the first seating portion 9214, or may be arranged to be able to raised and lowered from the first seating portion 9214. Through this, the plurality of first support portions 9215 may adjust a shape of an edge of the display substrate DP.

At least one of the first measurement portion 9217 or the first detection portion 9216 may be arranged outside or inside the first connection chamber 9211. For example, the first measurement portion 9217 and the first detection portion 9216 may be arranged outside or inside the first connection chamber 9211. In addition, one of the first measurement portion 9217 or the first detection portion 9216 may be arranged in one of the outside and the inside of the first connection chamber 9211, and the other one of the first measurement portion 9217 and the first detection portion 9216 may be arranged in the other one of the outside and the inside of the first connection chamber 9211.

The first detection portion 9216 described above may include a charge-coupled device (CCD) camera. In this case, the first detection portion 9216 may photograph the display substrate DP and the first seating portion 9214, to detect the positions of the display substrate DP and the first seating portion 9214.

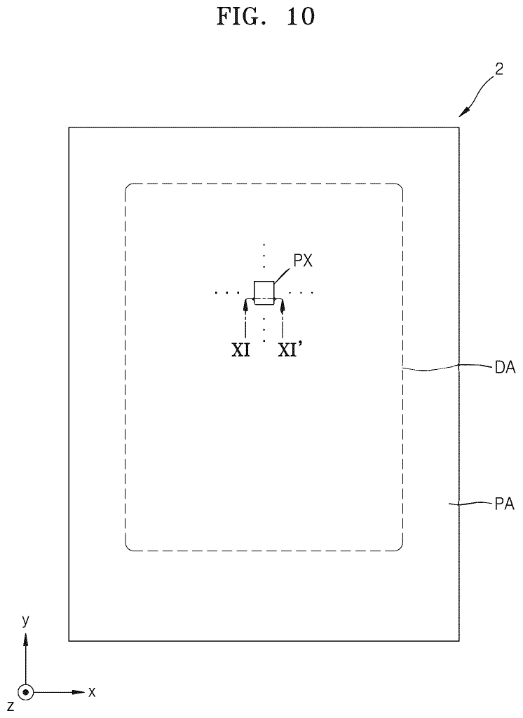

The first measurement portion 9217 may detect (measure) a thickness of a first layer of the display substrate DP. For example, the first measurement portion 9217 may detect a thickness of the first layer arranged in a display area DA (see FIG. 10) of the display substrate DP. In one or more other embodiments, in a same process as a process of detecting a thickness of the first layer arranged in the display area DA of the display substrate DP, the first measurement portion 9217 may detect a thickness of a first dummy layer arranged in the display area DA or peripheral area PA (see FIG. 10) of the display substrate DP. For convenience of description, a case in which the first measurement portion 9217 detects a thickness of the first dummy layer of the display substrate DP in the same process as the process of detecting a thickness of the first layer will be described in detail.

The first measurement portion 9217 may include at least one of an ellipsometer or a reflectometer. For example, the first measurement portion 9217 may include at least one of nanospec, a spectroscopic reflectometer, metapulse, X-ray reflection, or a fluorescence analyzer. The first measurement portion 9217 described above may radiate light or a laser beam to the outside, and may receive reflected light or laser beam.

To align the display substrate DP, a structure identical to or similar to a structure of the first seating portion 9214, the first support portion 9215, the first driving portion 9212, and the first measurement portion 9217, which are some of the elements of the first thickness detection unit, may be individually provided in the first transfer chamber 3100 in addition to the first connection portion 9210. In this case, the structure identical to or similar to that of the first seating portion 9214, the first support portion 9215, the first driving portion 9212, and the first measurement portion 9217 may align a position of the display substrate DP.

When a structure identical to or similar to that of the first thickness detection unit is arranged in the first transfer chamber 3100, the first thickness detection unit may be arranged in a space of the first transfer chamber 3100 that is similar to a space 4500 of the second transfer chamber 4100 not overlapping the second robot arm 4200 shown in FIG. 1. The first thickness detection unit may be arranged in a separate space connected to the first transfer chamber 3100. For example, in one or more embodiments, the first thickness detection unit may be arranged in a first thickness measurement portion connected to the first transfer chamber 3100, similar to the second thickness measurement portion 4400 connected to the second transfer chamber 4100.

In the apparatus 1 for manufacturing a display device described above, various layers may be sequentially stacked on the display substrate DP. For example, the display substrate DP may move to the flip portion 2000 after entering the loading portion 1000. The flip portion 2000 may invert the display substrate DP. In other words, in the loading portion 1000, the display substrate DP may be supplied from the outside so that layers stacked on a display substrate DP (or substrate) face upward. Thereafter, the flip portion 2000 may invert the display substrate DP so that the layers stacked on the display substrate DP (or substrate) face downward.

Thereafter, the display substrate DP may be introduced into the first transfer chamber 3100. In this case, the first robot arm 3200 may supply the display substrate DP from the flip portion 2000 to the first transfer chamber 3100. In this case, internal pressure of the flip portion 2000 and internal pressure of the first transfer chamber 3100 may be maintained same as or similar to each other.

The first robot arm 3200 may transfer the display substrate DP from the first transfer chamber 3100 to the first processing portion 3300. In this case, internal pressure of the first processing portion 3300 and internal pressure of the first transfer chamber 3100 may be maintained same as or similar to each other.

When the display substrate DP is introduced into the first processing portion 3300, a first layer may be formed on the display substrate DP in the first processing portion 3300. In this case, a material included in the first layer may be supplied to the display substrate DP in a third direction (e.g., the Z direction in FIG. 1). In other words, a material included in the first layer may be supplied toward the display substrate DP from a lower side of the display substrate DP.

After the first layer is located on the display substrate DP, the first robot arm 3200 may move the display substrate DP from the first processing portion 3300 to the first transfer chamber 3100. In this case, internal pressure of the first processing portion 3300 and internal pressure of the first transfer chamber 3100 may be maintained same as or similar to each other.

The first robot arm 3200 may move the display substrate DP from the first transfer chamber 3100 to the first connection portion 9210. In this case, internal pressure of the first transfer chamber 3100 and internal pressure of the first connection portion 9210 may be same as or similar to each other.

The first connection portion 9210 may arrange the display substrate DP so that a surface of the display substrate DP on which the first layer is located faces downward. In this case, the first thickness detection unit may measure a thickness of the first layer. A controller, which is separately provided, may control the first processing portion 3300 based on the measured thickness of the first layer. In one or more embodiments, the apparatus 1 for manufacturing a display device described above may have a separate controller, and may control each of elements of the apparatus 1 for manufacturing a display device based on the measured result. In this case, the controller may include various devices and structures, such as computers, portable terminals, or circuit boards.

For example, when the measured thickness of the first layer is different from a corresponding (e.g., preset) first thickness, the controller may control the first processing portion 3300 so that the thickness of the first layer is equal to or similar to the corresponding (e.g., preset) thickness. For example, in one or more embodiments, the controller may transmit again the display substrate DP on which the first layer is located to the first processing portion 3300, and may control the first processing portion 3300 to perform a process again so that the thickness of the first layer is equal to or similar to the first thickness. In this case, the controller may control the first processing portion 3300 to further form, on the display substrate DP, an additional first layer with a thickness equal to a difference between the measured thickness of the first layer and the first thickness. In one or more other embodiments, the display substrate DP on which the first layer has already been located may perform a subsequent operation, and when a new display substrate DP is arranged in the first processing portion 3300, the controller may control the first processing portion 3300 so that a thickness of the first layer located on the new display substrate DP corresponds to the corresponding (e.g., preset) first thickness. In one or more other embodiments, when forming a first layer on the display substrate DP again in addition to the first layer formed as described above, the controller may control the first processing portion 3300 so that a thickness of the first layer to be formed again is adjusted based on the measured thickness described above. In other words, the controller may control the first processing portion 3300 to adjust the thickness of the first layer to be formed again, so that a sum of the thickness of the first layer to be formed again and the thickness of the first layer previously formed is constant.

A method for forming the first layer with a thickness corresponding to the first thickness may include raising or lowering a temperature of a crucible containing a material forming the first layer, raising or lowering internal pressure of the first processing portion 3300, etc.

In addition to the above, the controller may control the apparatus 1 for manufacturing a display device so that a thickness of at least one of second, third, fourth, fifth, or sixth layers excluding the first layer may be adjusted based on the thickness of the first layer. In this case, the controller may control the apparatus 1 for manufacturing a display device to adjust a thickness of at least one layer, so that the layers are formed to complement each other based on changes in optical characteristics due to a thickness of each layer. For example, in one layer and another layer from among the first to sixth layers, in a state in which optical characteristics decrease as a thickness decreases, in which optical characteristics increase as a thickness increases, and in which a thickness of the one layer from among the first to sixth layers is less than a corresponding (e.g., preset) thickness, a thickness of the other layer from among the first to sixth layers may be formed to be greater than the corresponding (e.g., preset) thickness, so that, after at least two layers from among the first to sixth layers are stacked, optical characteristics of the entire structure of the stacked layers may correspond to designed optical characteristics.

The second robot arm 4200 may move the display substrate DP on which the first layer is located from the first connection portion 9210 to the second transfer chamber 4100. In this case, internal pressure of the first connection portion 9210 and internal pressure of the second transfer chamber 4100 may be equal to or similar to each other.

The second robot arm 4200 may move the display substrate DP from the second transfer chamber 4100 to the second processing portion 4300. In this case, internal pressure of the second transfer chamber 4100 and internal pressure of the second processing portion 4300 may be equal to or similar to each other. The second processing portion 4300 may form the second layer on the first layer. In this case, the second processing portion 4300 may supply a material included in the second layer toward the display substrate DP from a lower side of the display substrate DP.

The second robot arm 4200 may move the display substrate DP on which the second layer is formed from the second processing portion 4300 to the second transfer chamber 4100, and may move the display substrate DP from the second transfer chamber 4100 to the second thickness measurement portion 4400. In this case, internal pressure of the second processing portion 4300 and internal pressure of the second transfer chamber 4100 may be equal to or similar to each other, and internal pressure of the second transfer chamber 4100 and internal pressure of the second thickness measurement portion 4400 may be equal to or similar to each other.

The second thickness measurement portion 4400 may measure a thickness of at least one of the second layer or a second dummy layer that is formed in a same process as a process in which the second layer is formed. In this case, the second dummy layer may be located on another portion of the display substrate DP that is different from a portion of the display substrate DP on which the first dummy layer is formed. Hereinbelow, for convenience of description, it is described in detail that the second thickness measurement portion 4400 measures a thickness of the second dummy layer that is formed in the same process as a process in which the second layer is formed.

The controller may calculate a thickness of the second layer by measuring the thickness of the second dummy layer that is on the display substrate DP, and may compare the measured thickness of the second layer and a corresponding (e.g., preset) second thickness. In this case, the controller may control the second processing portion 4300 to correct the thickness of the second layer based on the measured thickness of the second layer, to correct a thickness of a layer different from the second layer, or, when a second layer is formed again on the display substrate DP on which the second layer is formed, to correct a thickness of the second layer that is formed again.

The second robot arm 4200 may withdraw the display substrate DP from the second thickness measurement portion 4400, and may move the withdrawn display substrate DP to the second processing portion 4300 or the second connection portion 9220 through the second transfer chamber 4100. In this case, internal pressure of the second thickness measurement portion 4400 and internal pressure of the second transfer chamber 4100 may be maintained equal to or similar to each other, or internal pressure of the second transfer chamber 4100 and internal pressure of the second processing portion 4300 may be maintained equal to or similar to each other, or internal pressure of the second transfer chamber 4100 and internal pressure of the second connection portion 9220 may be maintained equal to or similar to each other.

The display substrate DP arranged in the second connection portion 9220 may move from the second connection portion 9220 to the third transfer chamber 5100 through the third robot arm 5200. The third robot arm 5200 may transfer the display substrate DP to the third processing portion 5300, and may form at least one third layer and at least one third dummy layer on the display substrate DP. In this case, when a plurality of third layers are formed, in one or more embodiments, the plurality of third layers may be sequentially formed in a single third processing portion 5300. In one or more other embodiments, the display substrate DP may sequentially move a plurality of third processing portions 5300, in which a plurality of third layers that are different from each other may be located on the display substrate DP. In this case, the plurality of different third layers may be organic emission layers for emitting light of different colors. In this case, the plurality of third layers located on the display substrate DP through each of the plurality of third processing portions 5300 may be arranged in different areas of the display substrate DP so as not to overlap each other. In one or more other embodiments, the plurality of third layers may be sequentially stacked on the entire surface of the display substrate DP or in a corresponding area of the display substrate DP. In this case, between adjacent third layers, at least one layer from among the first layer, the second layer, the fourth layer, or the fifth layer may be arranged. In this case, the plurality of third dummy layers may be located on the display substrate DP to be spaced apart from each other. In addition, each of the plurality of third dummy layers may be located on the display substrate DP so as not to overlap the first dummy layer and the second dummy layer.

One or more embodiments are not limited thereto, and the plurality of different third layers may be formed in a plurality of different third clusters 5000. In this case, in one or more embodiments, the plurality of third clusters 5000 may be arranged in a row between the second cluster 4000 and the fourth cluster 6000, and may be connected through at least one third connection portion 9230. However, for convenience of description, it is described in detail below that third layers that are different from each other are formed in the plurality of third processing portions 5300 of a single third cluster 5000.

The third robot arm 5200 may move the display substrate DP on which at least one third layer is formed from the third processing portion 5300 to the third transfer chamber 5100 and then, may transfer the display substrate DP from the third transfer chamber 5100 to the third connection portion 9230.

The third thickness measurement unit arranged in the third connection portion 9230 may measure a thickness of at least one of the third layer or the third dummy layer. In this case, the third thickness measurement unit may sequentially measure at least one of thicknesses of a plurality of third layers or thicknesses of a plurality of third dummy layers. In this case, a thickness of each of the third layers may be obtained by forming each of the third layers, and third dummy layers respectively corresponding to the third layers, and then individually measuring at least one of a thickness of each of the third layers or a thickness of each of the third dummy layers, or by forming both a plurality of third layers and a plurality of third dummy layers respectively corresponding to the third layers, and then measuring at least one of a thickness of each of the third layers or a thickness of each of the third dummy layers. Hereinbelow, for convenience of description, it is mainly described in detail that a thickness of each of the third layers is calculated by measuring a thickness of the third dummy layers respectively corresponding to the third layers.

The controller may calculate a thickness of the third layer based on a thickness of the third dummy layer measured in the third thickness measurement unit. The controller may control the third processing portion 5300 to compare the thickness of the third layer calculated as above, with a corresponding (e.g., preset) third thickness, and may adjust the thickness of the third layer, or may control at least one of the first processing portion 3300, the second processing portion 4300, the fourth processing portion 6300, the fifth processing portion 7300, or the sixth processing portion 8300 to adjust a thickness of at least one of the first layer, the second layer, the fourth layer, the fifth layer, or the sixth layer excluding the third layer.

When the third layer is formed on the display substrate DP as described above, depending on a movement path of the display substrate DP, the third transfer chamber 5100 and each third processing portion 5300, or the third transfer chamber 5100 and the third connection portion 9230, may be selectively connected to each other. In this case, when the display substrate DP moves, internal pressure of the third transfer chamber 5100 and internal pressure of each third processing portion 5300 may be equal to or similar to each other, or internal pressure of the third transfer chamber 5100 and internal pressure of the third connection portion 9230 may be equal to or similar to each other.

The fourth robot arm 6200 may move the display substrate DP from the third connection portion 9230 to the fourth transfer chamber 6100, and then may transfer the display substrate DP from the fourth transfer chamber 6100 to the fourth processing portion 6300. In this case, depending on the movement path of the display substrate DP, internal pressure of the third connection portion 9230 and internal pressure of the fourth transfer chamber 6100, or internal pressure of the fourth transfer chamber 6100 and internal pressure of the fourth processing portion 6300, may be equal to or similar to each other.

A fourth layer and a fourth dummy layer may be formed on the display substrate DP in the fourth processing portion 6300. The display substrate DP on which the fourth layer is formed may move from the fourth processing portion 6300 to the fourth transfer chamber 6100 through the fourth robot arm 6200, and may move from the fourth transfer chamber 6100 to the fourth connection portion 9240. In this case, internal pressure of the fourth processing portion 6300 and internal pressure of the fourth transfer chamber 6100, or internal pressure of the fourth transfer chamber 6100 and internal pressure of the fourth connection portion 9240, may be equal to or similar to each other.

In this case, a thickness of at least one of the fourth layer or the fourth dummy layer may be measured through the fourth thickness measurement unit arranged in the fourth connection portion 9240. Hereinbelow, for convenience of description, it is mainly described in detail that the fourth thickness measurement unit measures a thickness of the fourth dummy layer, and that the controller calculates a thickness of the fourth layer based on the thickness of the fourth dummy layer.

The fourth dummy layer described above may be located on the display substrate DP so as not to overlap the first dummy layer, the second dummy layer, and the third dummy layer.

The controller may control the fourth processing portion 6300 to compare the thickness of the fourth layer calculated based on the thickness of the fourth dummy layer with a corresponding (e.g., preset) fourth thickness. The controller may adjust the thickness of the fourth layer, or may control at least one of the first processing portion 3300, the second processing portion 4300, the third processing portion 5300, the fifth processing portion 7300, or the sixth processing portion 8300 to adjust a thickness of at least one layer from among the first layer, the second layer, the third layer, the fifth layer, or the sixth layer excluding the fourth layer.

The fifth robot arm 7200 may move the display substrate DP arranged in the fourth connection portion 9240 from the fourth connection portion 9240 to the fifth transfer chamber 7100, and then may move the display substrate DP from the fifth transfer chamber 7100 to the fifth processing portion 7300. Thereafter, when the fifth layer and the fifth dummy layer are formed on the display substrate DP, the fifth robot arm 7200 may move the display substrate DP from the fifth processing portion 7300 to the fifth transfer chamber 7100. In this case, depending on a movement path of the display substrate DP, internal pressure of the fourth connection portion 9240 and internal pressure of the fifth transfer chamber 7100, or internal pressure of the fifth transfer chamber 7100 and internal pressure of the fifth processing portion 7300, may be equal to or similar to each other.

The fifth robot arm 7200 may move the display substrate DP on which the fifth layer is formed from the fifth transfer chamber 7100 to the fifth connection portion 9250. In this case, the fifth thickness measurement unit of the fifth connection portion 9250 may measure a thickness of at least one of the fifth layer or the fifth dummy layer. In this case, the fifth dummy layer may be located on the display substrate DP so as not to overlap the first dummy layer, the second dummy layer, the third dummy layer, and the fourth dummy layer. Hereinbelow, for convenience of description, it is mainly described in detail that the fifth thickness measurement unit measures a thickness of the fifth dummy layer, and that the controller calculates a thickness of the fifth layer based on the thickness of the fifth dummy layer.

The controller may control the fifth processing portion 7300 to compare the calculated thickness of the fifth layer with a corresponding (e.g., preset) fifth thickness, and may adjust the thickness of the fifth layer, or may control at least one of the first processing portion 3300, the second processing portion 4300, the third processing portion 5300, the fourth processing portion 6300, or the sixth processing portion 8300 to adjust a thickness of at least one of the first layer, the second layer, the third layer, the fourth layer, or the sixth layer excluding the fifth layer.

The sixth robot arm 8200 may move the display substrate DP from the fifth connection portion 9250 to the sixth transfer chamber 8100, and may move the display substrate DP from the sixth transfer chamber 8100 to the sixth processing portion 8300. In this case, depending on a movement path of the display substrate DP, internal pressure of the fifth connection portion 9250 and internal pressure of the sixth transfer chamber 8100, or internal pressure of the sixth transfer chamber 8100 and internal pressure of the sixth processing portion 8300 may be equal to or similar to each other.

The sixth processing portion 8300 may form a sixth layer and a sixth dummy layer on the display substrate DP. In this case, a plurality of sixth processing portions 8300 may form a sixth layer including different materials from each other. For example, the sixth layer may include a sixth-1 layer, a sixth-2 layer, a sixth-3 layer, a sixth-4 layer, and a sixth-5 layer. The sixth-1 layer may be a common electrode, the sixth-2 layer may be a protective layer (or capping layer), and the sixth-3 layer may be a first inorganic encapsulation layer described below, the sixth-4 layer may include an organic encapsulation layer described below, and the sixth-5 layer may include a second inorganic encapsulation layer described below. When each of the sixth layers are formed on the display substrate DP, the sixth robot arm 8200 may move the display substrate DP from one of the plurality of sixth processing portions 8300 to the sixth transfer chamber 8100 and then may move the display substrate DP from the sixth transfer chamber 8100 to another one of the plurality of sixth processing portions 8300. When the plurality of sixth layers described above are formed, a plurality of sixth dummy layers may be formed to respectively correspond to the plurality of sixth layers. In addition, the plurality of sixth dummy layers may be arranged in different areas of the display substrate DP from each other so as not to overlap each other.

When the sixth layer is formed on the display substrate DP, the sixth robot arm 8200 may move the display substrate DP from the sixth processing portion 8300 to the sixth transfer chamber 8100, and then may move the display substrate DP from the sixth transfer chamber 8100 to the sixth connection portion 9260. The sixth thickness measurement unit arranged in the sixth connection portion 9260 may measure a thickness of the sixth layer. In this case, the sixth thickness measurement unit may measure at least one of a thickness of each of the plurality of sixth layers or a thickness of each of the plurality of sixth dummy layers. In one or more other embodiments, the sixth thickness measurement unit may measure only one of a thickness of one of the plurality of sixth layers and a thickness of one of the plurality of sixth dummy layers. Hereinbelow, for convenience of description, it is mainly described in detail that the sixth thickness measurement unit measures only a thickness of a sixth dummy layer corresponding to the sixth-3 layer, which is an organic encapsulation layer from among the plurality of sixth layers.

In this case, the thickness of the sixth dummy layer corresponding to the sixth-3 layer measured in the sixth thickness measurement unit may be measured, and the controller may calculate a thickness of the sixth-3 layer based on the thickness of the sixth dummy layer measured in the sixth thickness measurement unit. The controller may compare the calculated thickness of the sixth-3 layer with a corresponding (e.g., preset) sixth-3 thickness (or sixth thickness). Through this, the controller may control the corresponding sixth processing portion 8300 to adjust the thickness of the sixth-3 layer, or to adjust a thickness of at least one of the remaining sixth layers excluding the sixth-3 layer. In one or more other embodiments, at least one of the first processing portion 3300, the second processing portion 4300, the third processing portion 5300, the fourth processing portion 6300, or the fifth processing portion 7300 may be controlled so that a thickness of at least one of the remaining first layer, second layer, third layer, fourth layer, or fifth layer excluding the sixth layer may be adjusted.

The display substrate DP on which the sixth layer is formed may move to the unloading portion 9100. In this case, in one or more embodiments, the unloading portion 9100 may have a separate robot arm. In addition, a separate flip portion 2000 may be provided between the unloading portion 9100 and the sixth processing portion 8300, so that a posture of the display substrate DP is inverted, thereby changing a posture of the display substrate DP.

Accordingly, in the apparatus 1 for manufacturing a display device and a method of manufacturing a display device, optical characteristics (e.g., wavelength, energy, intensity, etc. of light) of a manufactured display device may be similar to corresponding (e.g., preset) optical characteristics.

In the apparatus 1 for manufacturing a display device and a method of manufacturing a display device, a thickness of at least one of a plurality of layers formed on the display substrate DP during a manufacturing process may be precisely measured. In this case, the first thickness measurement unit, the second thickness measurement unit, the third thickness measurement unit, the fourth thickness measurement unit, the fifth thickness measurement unit, and the sixth thickness measurement unit may operate similarly to each other. Hereinbelow, for convenience of description, a method of measuring a thickness of a first layer through a first thickness measurement unit is described in detail.

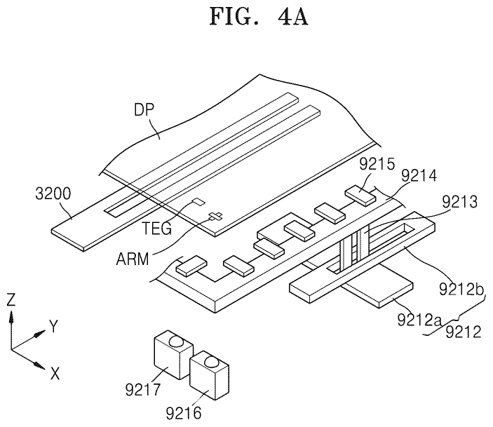

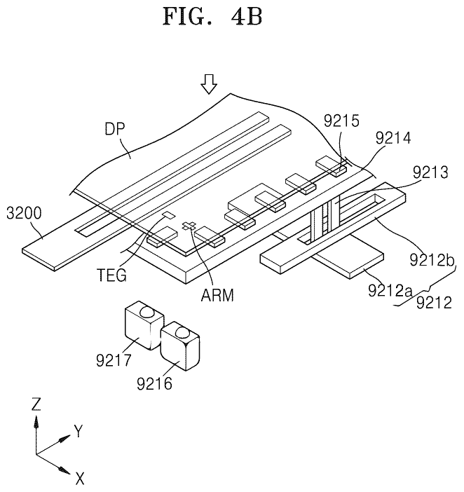

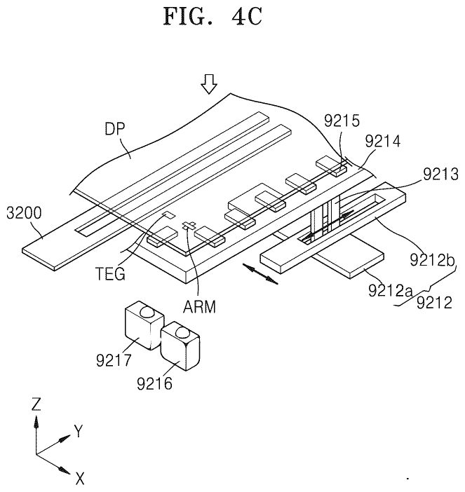

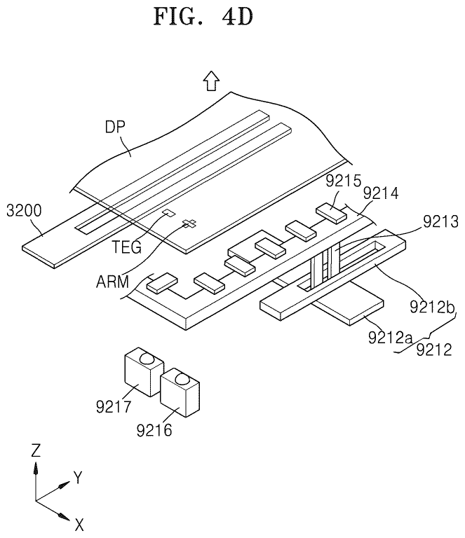

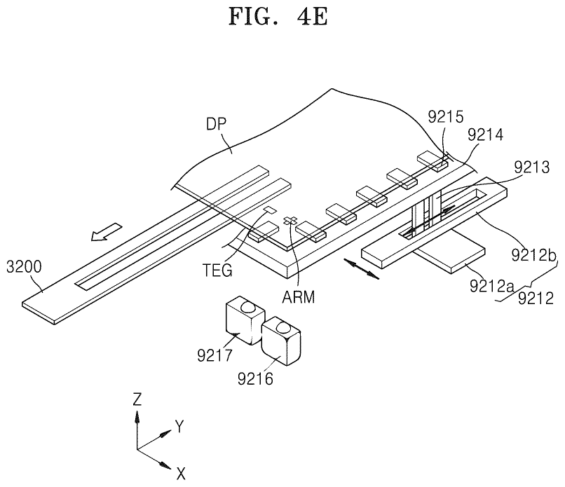

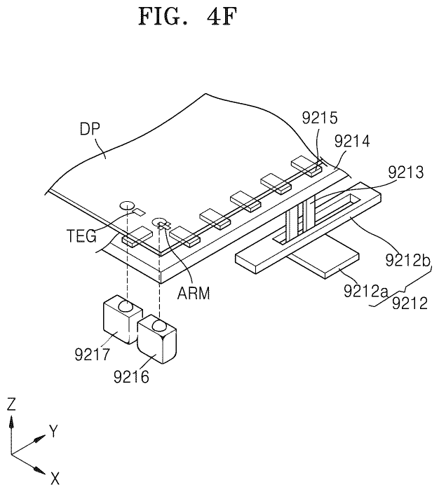

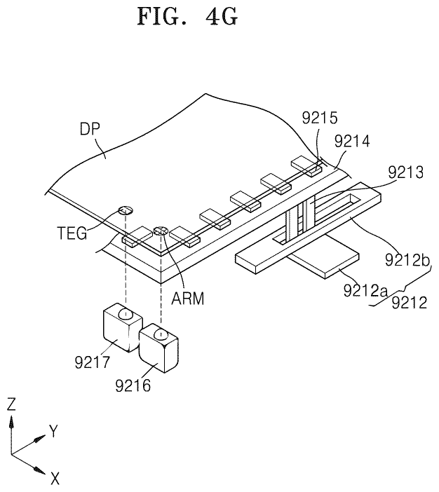

FIGS. 4A to 4G are partial perspective views schematically illustrating part of an operation of the apparatus 1 for manufacturing a display device, shown in FIG. 1.

Referring to FIG. 4A, the display substrate DP on which a first layer and a first dummy layer TEG are formed may be arranged in a first connection portion, in one or more embodiments. In this case, the first dummy layer TEG, which is performed in the same process as a process of the first layer, and which is arranged at an edge of the display substrate DP, may be located on the display substrate DP. In this case, in one or more embodiments, the first dummy layer TEG may be in direct contact with a substrate of the display substrate DP, or may be located on an electrode layer in a state in which a layer, such as a buffer layer, a gate-insulating layer, and an electrode layer (source electrode or drain electrode), which are described below, is stacked on the substrate, in one or more embodiments. In addition, the first dummy layer TEG may be arranged only in a corresponding area of the display substrate DP. In this case, in a plan view, the first dummy layer TEG may have an island shape, and may be completely disconnected from the first layer.

At least one dummy layer including the first dummy layer TEG may be provided on the display substrate DP. For example, a plurality of dummy layers may be provided to correspond to the first layer, a second layer, a third layer, a fourth layer, a fifth layer, and a sixth layer, respectively. In this case, in each of the plurality of dummy layers, at least two of the first, second, third, fourth, fifth, and/or sixth layers are not sequentially stacked, but one dummy layer may correspond to one of the first, second, third, fourth, fifth, or sixth layers. Accordingly, in a plan view, the plurality of dummy layers are arranged in different portions of the display substrate DP from each other so as not to overlap each other.

The first robot arm 3200 may move the display substrate DP from a first transfer chamber to a first connection chamber, in one or more embodiments. The first robot arm 3200 may move the display substrate DP to a corresponding (e.g., preset) position inside the first connection chamber. In addition, the first seating portion 9214 may be arranged at a corresponding (e.g., preset) initial position. A posture of the first seating portion 9214 may maintain a corresponding (e.g., preset) initial set posture. For example, the first seating portion 9214 may be arranged inside the first connection chamber so that one point of the first seating portion 9214 (e.g., a center of an opening area of the first seating portion 9214) corresponds to a corresponding (e.g., preset) first center set position. In this case, the first center set position may be a center of the first connection chamber.

Referring to FIG. 4B, the first robot arm 3200 may descend, and may mount the display substrate DP on the first support portion 9215. In this case, due to various causes, such as design errors in the first robot arm 3200, operation of the first robot arm 3200, a movement speed of the first robot arm 3200, etc., the display substrate DP may be twisted on the first robot arm 3200, or one point of the display substrate DP (e.g., a center of the display substrate DP) may not be arranged at an accurate position. In other words, when the first robot arm 3200 moves the display substrate DP into the first connection chamber and arranges the display substrate DP to be spaced apart on the first seating portion 9214, one point of the display substrate DP must be arranged at the first center set position. However, when the display substrate DP is located on the first seating portion 9214 due to the causes described above, the one point of the display substrate DP and the first center set position may be deviated from each other. In addition, the display substrate DP may be in a twisted state differently from a corresponding (e.g., preset) posture.

Referring to FIG. 4C, after the display substrate DP may be seated on the first support portion 9215, the first support portion 9215 may be moved so that a position of one point of the display substrate DP corresponds to the first center set position. In addition, the first support portion 9215 may be moved so that a posture of the display substrate DP corresponds to a corresponding (e.g., preset) posture. In this case, the first seating portion 9214 may be twisted from an initial state thereof, or may be arranged at a position different from an initial position thereof.

For example, the first detection portion 9216 may photograph an edge of the substrate of the display substrate DP, or an alignment mark ARM located on the substrate of the display substrate DP. Through the photographed edge of the display substrate DP or the alignment mark ARM, a position and posture of the display substrate DP may be calculated. In addition, the first detection portion 9216 may photograph the first seating portion 9214. Based on the photographed display substrate DP and first seating portion 9214, a relative position between the display substrate DP and the first seating portion 9214 may be identified. Thereafter, after the display substrate DP is seated on the first seating portion 9214, the first robot arm 3200 may lower the display substrate DP, and may arrange the display substrate DP on the first support portion 9215. When the first seating portion 9214 linearly moves so that the edge or the alignment mark ARM of the display substrate DP corresponds to a corresponding (e.g., preset) alignment position, the display substrate DP may linearly move so that one point of the display substrate DP corresponds to the first center set position. In addition, the display substrate DP may be rotated by linearly moving first support portion 9215 so that the posture of the display substrate DP corresponds to a corresponding (e.g., preset) posture.

Referring to FIG. 4D, after a position of the first seating portion 9214 is moved, the first robot arm 3200 may support and raise the display substrate DP again. In this case, the display substrate DP may be separated from the first support portion 9215. In addition, the first driving portion 9212 may move the first support portion 9215 so that the first seating portion 9214 corresponds to an initial position and an initial set posture. Thereafter, after the display substrate DP is located on the first support portion 9215, the first robot arm 3200 may be separated from the display substrate DP, and may return to the first transfer chamber, in one or more embodiments.

Referring to FIG. 4E, when the display substrate DP is raised and lowered through the first robot arm 3200, the posture of the display substrate DP may be twisted or the position of the display substrate DP may vary.

Referring to FIG. 4F, a position of the display substrate DP may be aligned. For example, the first detection portion 9216 may photograph an edge of the display substrate DP or the alignment mark ARM. The position and posture of the display substrate DP may be calculated by performing comparison with an alignment position based on the photographed edge of the display substrate DP or the photographed alignment mark ARM. The first seating portion 9214 may linearly move so that the edge of the display substrate DP or the alignment mark ARM corresponds to the alignment position.

Referring to FIG. 4G, when the operation described above is performed, positions of the first dummy layer TEG and the first measurement portion 9217 may be aligned to some extent. However, there may be cases where a center of the first dummy layer TEG and a center of the first measurement portion 9217 do not correspond to each other. In this case, it may be difficult to accurately measure a thickness of the first dummy layer TEG. To reduce or prevent the likelihood of this problem, the first measurement portion 9217 may detect a position and posture of the first dummy layer TEG, and may change the position and posture of the display substrate DP based on the detection result. For example, one point (e.g., center) of the first dummy layer TEG measured by the first measurement portion 9217 may be compared to a corresponding (e.g., preset) dummy position. Through this, the position and posture of the first dummy layer TEG may be calculated. In this case, the first driving portion 9212 may linearly move the first seating portion 9214 based on the detected position and posture of the first dummy layer TEG.

When the process described above is completed, the first measurement portion 9217 may measure a thickness of the first dummy layer TEG. In this case, the first measurement portion 9217 may precisely measure the thickness of the first dummy layer TEG by radiating laser beam or light to the first dummy layer TEG and then analyzing a wavelength of reflected laser beam or light, etc.

As described above, a method of measuring a thickness of the first dummy layer TEG may be applied similarly to a thickness of the second layer, a thickness of the third layer, a thickness of the fourth layer, a thickness of the fifth layer, and a thickness of the sixth layer. In other words, a thickness of a dummy layer that is formed in the same process as each layer formed in an apparatus 1 (see FIG. 1) for manufacturing a display device may be measured through a process similar to that described above.

Thus, in the apparatus 1 for manufacturing a display device and the method for manufacturing a display device, the thickness of each layer may be precisely controlled by precisely measuring the thickness of a dummy layer. In addition, in the apparatus 1 for manufacturing a display device and the method for manufacturing a display device, measurement errors due to an error between a position of a measurement portion and a position of a dummy layer may be reduced by precisely controlling the positions of the dummy layer and the measurement portion.

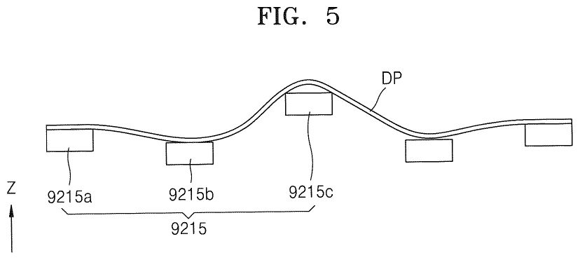

FIG. 5 is a front view schematically illustrating part of the first support portion 9215 shown in FIG. 3.

Referring to FIG. 5, when a thickness of each layer is measured by measuring a thickness of a dummy layer, in one or more embodiments, the thickness of each layer may be affected by a curvature of a curved surface of the display substrate DP (or substrate). In other words, when a plurality of first support portions 9215 support the display substrate DP, the display substrate DP may be curved due to a size, area, weight, etc. of the display substrate DP. In this case, a portion of the display substrate DP on which the dummy layer described above is located may have a different shape of curved surface in different display substrates DP. In this case, even when the dummy layer is formed identically in a same area of the different display substrates DP, values measured by the first measurement portion 9217 (see FIG. 4G) may be different from each other. In this case, when the process described above is performed based on the value measured by the first measurement portion 9217, it may become difficult to manufacture a display device of constant quality.

Accordingly, to manufacture a display device of uniform quality, a plurality of first support portions 9215 may be arranged at different heights from each other, so as to support the display substrate DP to have a constant shape.

For example, one of the plurality of first support portions 9215, another one of the plurality of first support portions 9215, and still another one of the plurality of first support portions 9215 may be respectively arranged at different heights from each other on one surface of a first seating portion, in one or more embodiments. For example, the plurality of first support portions 9215 may include a first-1 support portion 9215a, a first-2 support portion 9215b, and a first-3 support portion 9215c. In this case, the first-1 support portion 9215a may be located at a higher position than the first-2 support portion 9215b, the first-2 support portion 9215b may be located at a lower position than the first-3 support portion 9215c, and the first-3 support portion 9215c may be located at a higher position than the first-1 support portion 9215a. In addition, the first-2 support portion 9215b and the first-3 support portion 9215c may be symmetrical to each other with respect to the first-1 support portion 9215a. In this case, the plurality of first support portions 9215 may support one edge of the display substrate DP in a “W” shape. In this case, a portion at which the first dummy layer TEG is located always has a constant shape in the plurality of display substrates DP, thereby reducing measurement errors due to the shape of the display substrate DP. In this case, a shape in which the display substrate DP is supported is not limited to that described above, and may include all structures that support the display substrate DP while maintaining the shape of the display substrate DP constant.

The structure described above is not necessarily applied only to the first thickness measurement unit. For example, at least one of a second support portion of the second thickness measurement unit, a third support portion of the third thickness measurement unit, a fourth support portion of the fourth thickness measurement unit, a fifth support portion of the fifth thickness measurement unit, or a sixth support portion of the sixth thickness measurement unit may have a shape identical to or similar to a shape of the first support portion 9215.

Thus, in the apparatus 1 (see FIG. 1) for manufacturing a display device and the method of manufacturing a display device, measurement errors due to a curvature of a substrate may be reduced.

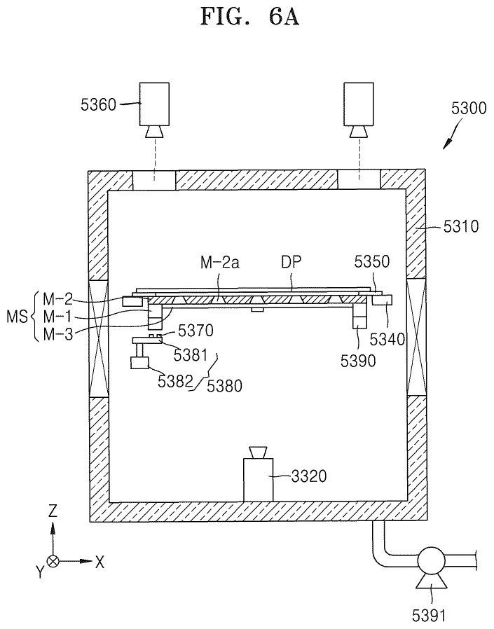

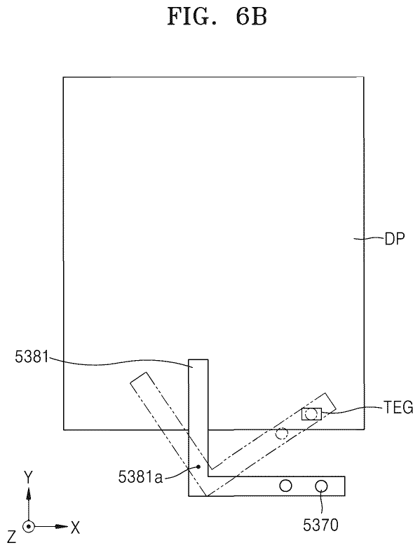

FIG. 6A is a cross-sectional view schematically illustrating a third processing portion 5300 of an apparatus 1 (see FIG. 1) for manufacturing a display device, according to one or more other embodiments. FIG. 6B is a plan view schematically illustrating a rotation portion 5380 and a display substrate DP that are shown in FIG. 6A.

Referring to FIGS. 6A and 6B, the third processing portion 5300 may include a third processing chamber 5310, a third thickness measurement unit, a third mask support portion 5390, a third deposition source 3320, and a third processing pressure regulation portion 5391.

The third processing chamber 5310 may have a space formed therein, and may accommodate the display substrate DP and a mask assembly MS. In this case, the third processing chamber 5310 may have an opening to allow the display substrate DP and the mask assembly MS to move, and may include an opening/closing portion, such as a gate valve that may open and close the opening.

The mask assembly MS described above may include a mask frame M-1 and a mask sheet M-2. The mask frame M-1 may have/define an opening area at a center thereof, and may be in the form of a picture frame. The mask sheet M-2 may be located in a tensioned state on the mask frame M-1, and may shield the opening area of the mask frame M-1. In this case, the mask sheet M-2 may include at least one opening M-2a. This opening M-2a may include one or more openings, depending on a layer in which the opening M-2a is formed. For example, in a layer located on a front surface of the display substrate DP, a single opening M-2a may be provided and formed identically or similar to the opening area. In one or more other embodiments, when the opening M-2a is arranged in a pattern in a corresponding portion of the display substrate DP, similar to an organic emission layer, a plurality of openings M-2a may be provided to be spaced apart from each other. Hereinbelow, because the third layer corresponds to an organic emission layer, for convenience of description, a case where the third layer includes a plurality of layers is mainly described in detail.

In addition to the above, the mask assembly MS may further include a support stick M-3. The support stick M-3 may be located on the mask frame M-1, may divide the opening area into a plurality of opening areas, and may support the mask sheet M-2. In this case, in one or more embodiments, the support stick M-3 may include a plurality of support sticks M-3, and the plurality of support sticks M-3 may be arranged spaced apart from each other in a same direction. In one or more other embodiments, some of the plurality of support sticks M-3 may be arranged spaced apart from each other in a first direction, and other ones of the plurality of support sticks M-3 may be arranged spaced apart from each other in a second direction. In this case, one of the plurality of support sticks M-3 and another one of the plurality of support sticks M-3 may cross each other.

The third thickness measurement unit may include a third seating portion 5340, a third support portion 5350, a third detection portion 5360, a third measurement portion 5370, and a rotation portion 5380. In this case, the third seating portion 5340, the third support portion 5350, the third detection portion 5360, and the third measurement portion 5370 are respectively identical to or similar to the first seating portion 9214, the first support portion 9215, the first detection portion 9216, and the first measurement portion 9217 described above with reference to FIG. 3, and redundant descriptions thereof are omitted.

At least one of the third detection portion 5360 or the third measurement portion 5370 may be located on the rotation portion 5380, and the rotation portion 5380 may rotate at least one of the third detection portion 5360 or the third measurement portion 5370. In this case, the rotation portion 5380 may rotate depending on a process of forming a third layer. In this case, the rotation portion 5380 may include a rotation plate 5381 on which at least one of the third detection portion 5360 or the third measurement portion 5370 is located, and a rotation driving portion 5382 having a motor connected to the rotation plate 5381. Hereinbelow, for convenience of description, a case in which only the third measurement portion 5370 is located on the rotation plate 5381 is mainly described in detail.

The mask assembly MS may be seated on the third mask support portion 5390. The third mask support portion 5390 may have the mask assembly MS seated thereon and may adjust a position of the mask assembly MS.

The third deposition source 3320 may be arranged inside the third processing chamber 5310, and may supply a deposition material to the display substrate DP. In this case, the third deposition source 3320 may accommodate a deposition material therein, and may apply heat to the deposition material to vaporize or sublimate the deposition material.

The third processing pressure regulation portion 5391 may be connected to the third processing chamber 5310, and may regulate internal pressure of the third processing chamber 5310. For example, the third processing pressure regulation portion 5391 may have a pipe connected to the third processing chamber 5310, and may have a pump that is located on the pipe. In this case, depending on an operation of the pump, outside air may be supplied to the third processing chamber 5310, or air inside the third processing chamber 5310 may be discharged to the outside.

Meanwhile, when the third processing portion 5300 is operated, the position of the display substrate DP may be aligned. In this case, similar to the description provided above with reference to FIGS. 4A to 4E, the position of the display substrate DP is adjusted so that the display substrate DP may be seated on the third support portion 5350.

When the process described above is completed, the mask assembly MS is located on the third mask support portion 5390, and then, a position between the mask assembly MS and the display substrate DP may be photographed by using the third detection portion 5360. Based on the above, a relative position of the mask assembly MS and the display substrate DP may be calculated so that the mask assembly MS and the display substrate DP may be aligned with each other. In this case, the third detection portion 5360 may be arranged outside the third processing chamber 5310, and may photograph the inside of the third detection portion 5360 through a transmission window of the third processing chamber 5310.

When the alignment of the mask assembly MS and the display substrate DP is completed, the third processing pressure regulation portion 5391 may adjust pressure of the inside of the third processing chamber 5310 from a state similar to atmospheric pressure to a state similar to vacuum. Thereafter, a deposition material may be supplied through the third deposition source 3320, so that a third layer may be located on the display substrate DP. In this case, the third layer may be an organic emission layer, as described above.

The organic emission layer described above may form a dummy layer TEG (i.e., third dummy layer), which is on a same layer as the third layer, on one area of the display substrate DP. When the formation of the third layer on the display substrate DP is completed, the mask assembly MS may be pulled out of the third processing chamber 5310. Thereafter, the rotation portion 5380 may operate to rotate the third measurement portion 5370, so that the third measurement portion 5370 may be arranged to correspond to the dummy layer TEG. In this case, to arrange the third measurement portion 5370 and the dummy layer TEG to correspond to each other, operations similar to those of FIGS. 4F and 4G described above may be performed.

After a thickness of the dummy layer TEG is measured by the third measurement portion 5370, based on the thickness of the dummy layer TEG, a thickness of the third layer may be adjusted, or a thickness of another layer excluding the third layer may be adjusted. For example, because the third measurement portion 5370 is arranged inside the third processing chamber 5310, and because the thickness of the third layer may be calculated in a state in which the display substrate DP is not pulled out of the third measurement portion 5370, the thickness of the third layer may be adjusted to correspond to a corresponding (e.g., preset) third thickness.

In one or more other embodiments, the rotation plate 5381 of the rotation portion 5380 may be arranged between the display substrate DP and the mask assembly MS. In this case, the third detection portion 5360 may be arranged outside or inside the third processing chamber 5310, as described above. In addition, in this case, the rotation plate 5381 of the rotation portion 5380 may be rotated (e.g., about point 5381a), and may be arranged between the display substrate DP and the mask assembly MS, and thus, the mask assembly MS may not be pulled out of the third processing chamber 5310 to measure a thickness of a third dummy layer.

In one or more other embodiments, the third processing portion 5300 may support the display substrate DP and the mask assembly MS through a single structure (e.g., a shuttle, etc.). In this case, the third seating portion 5340 and the third mask support portion 5390 may be integrally formed. In addition, the rotation portion 5380 may be connected to at least one of the third seating portion 5340 or the third mask support portion 5390.

In this case, when a deposition process is performed, the rotation plate 5381 of the rotation portion 5380 may be arranged so as not to interfere with a path of a deposition material. After the deposition process is completed, the rotation plate 5381 of the rotation portion 5380 may be rotated to measure the thickness of the third dummy layer, and in a plan view, the rotation plate 5381 may overlap the display substrate DP.

A first processing portion, a second processing portion, a fourth processing portion, and a fifth processing portion may be identical to or similar to the third processing portion 5300 described above. In this case, when layers formed in the first processing portion, the second processing portion, the fourth processing portion, and the fifth processing portion are formed on an entire surface of the display substrate DP, a mask sheet used for deposition may have a single opening.

Accordingly, in the apparatus 1 for manufacturing a display device, a thickness of a layer may be measured in a processing portion that forms one layer.

In one or more embodiments, the structure described above may be applied to at least one of the first thickness measurement unit, the second thickness measurement unit, the fourth thickness measurement unit, the fifth thickness measurement unit, or the sixth thickness measurement unit.

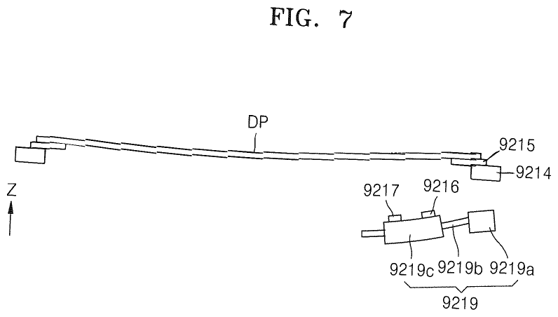

FIG. 7 is a front view schematically illustrating a portion of an apparatus for manufacturing a display device, according to one or more other embodiments.

In FIG. 7, because the apparatus for manufacturing a display device is identical to or similar to that described with reference to FIGS. 1 to 3, and for convenience of description, differences are mainly described in detail.

In one or more embodiments, the first thickness measurement unit may include the first seating portion 9214, the first support portion 9215, and the first detection portion 9216, the first measurement portion 9217, and a movement driving portion 9219. In this case, because the first seating portion 9214 and the first support portion 9215 are identical to or similar to those described above with reference to FIG. 1, and detailed descriptions thereof are omitted.

The movement driving portion 9219 may include a driving force generation portion 9219a on which a movement block 9219c is seated to move itself, a guide portion 9219b connected to the driving force generation portion 9219a to guide movement of the movement block 9219c, and the movement block 9219c on which at least one of the first detection portion 9216 or the first measurement portion 9217 is located. In this case, the movement block 9219c may move along a curve, depending on an operation of the driving force generation portion 9219a. For example, in the movement block 9219c, when the display substrate DP is located on the first support portion 9215, the display substrate DP may be sagging due to a load. In this case, a portion of the display substrate DP that the first measurement portion 9217 must measure may be round. A movement path of the movement block 9219c may correspond to a round portion of the display substrate DP.

In this case, each of the first detection portion 9216 and the first measurement portion 9217 may be arranged such that a signal is incident in a direction perpendicular to one surface of the display substrate DP. In other words, each of the first detection portion 9216 and the first measurement portion 9217 may be located on the movement block 9219c such that a longitudinal direction is tilted from a load direction rather than the load direction. Through the above, a problem of a signal path being distorted or a signal not being received due to sagging of the display substrate DP may be reduced.

In one or more embodiments, the structure described above may be applied to at least one of the second thickness measurement unit, the third thickness measurement unit, the fourth thickness measurement unit, the fifth thickness measurement unit, or the sixth thickness measurement unit.

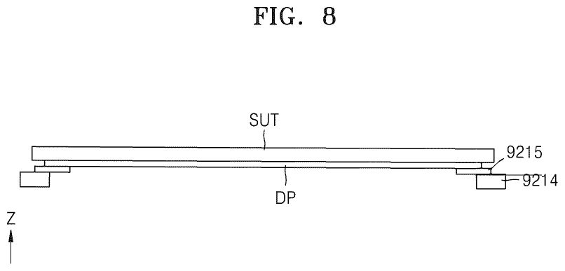

FIG. 8 is a front view schematically illustrating a portion of an apparatus for manufacturing a display device, according to one or more other embodiments.

In FIG. 8, because the apparatus for manufacturing a display device is identical to or similar to that described with reference to FIGS. 1 to 3, and for convenience of description, differences are mainly described in detail.

In one or more embodiments, the first thickness measurement unit may include the first seating portion 9214, the first support portion 9215, a first detection portion, and a first measurement portion. In this case, the first seating portion 9214, the first support portion 9215, the first detection portion, and the first measurement portion are similar to those described above with reference to FIG. 1, and redundant descriptions thereof are omitted.

The first thickness measurement unit may further include a substrate fixing portion SUT, which is a substrate pressing portion arranged to face the first seating portion 9214. The substrate fixing portion SUT may be in the form of an electrostatic chuck or an adhesive chuck, and may keep the display substrate DP flat. In this case, the display substrate DP may form one flat surface, a plurality of first support portions 9215 may be arranged at a same height.

In addition, in this case, one surface of the display substrate DP is flat when a thickness of a dummy layer is measured through the first measurement portion 9217, and thus, measurement errors due to bending of the display substrate DP due to a load of the display substrate DP may be reduced.

In one or more embodiments, the structure described above may be applied to at least one of the second thickness measurement unit, the third thickness measurement unit, the fourth thickness measurement unit, the fifth thickness measurement unit, or the sixth thickness measurement unit.

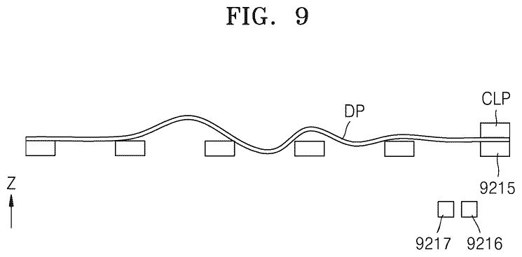

FIG. 9 is a front view illustrating a portion of an apparatus for manufacturing a display device, according to one or more other embodiments.

In FIG. 9, because the apparatus for manufacturing a display device is identical to or similar to that described with reference to FIGS. 1 to 3, and for convenience of description, differences are mainly described in detail.

The first thickness measurement unit may include the first seating portion, the first support portion 9215, the first detection portion 9216, and the first measurement portion 9217, in one or more embodiments. In this case, the first seating portion, the first support portion 9215, the first detection portion 9216, and the first measurement portion 9217 are similar to those described above with reference to FIG. 1, and redundant descriptions thereof are omitted.

The first thickness measurement unit may further include a substrate clamp CLP, which is a substrate pressing portion arranged to face a portion of the first support portion 9215. The substrate clamp CLP may be in the form of an electrostatic chuck or an adhesive chuck, and may keep a corresponding portion of the display substrate DP flat. For example, the substrate clamp CLP may fix an edge portion of the display substrate DP at which a dummy layer is arranged, so that the edge forms one flat surface.

In this case, one surface of the display substrate DP is flat when a thickness of the dummy layer is measured through the first measurement portion 9217, and thus, measurement errors due to bending of the display substrate DP due to a load of the display substrate DP may be reduced.

In one or more embodiments, the structure described above may be applied to at least one of the second thickness measurement unit, the third thickness measurement unit, the fourth thickness measurement unit, the fifth thickness measurement unit, or the sixth thickness measurement unit.

FIG. 10 is a plan view schematically illustrating a display device 2 according to one or more embodiments.

Referring to FIG. 10, the display device 2 may include a display area DA and a peripheral area PA that is positioned outside the display area DA. The display device 2 may provide an image through an array of a plurality of pixels PX two-dimensionally arranged in the display area DA.

The peripheral area PA is an area in which no image is provided, and may entirely or partially surround the display area DA. In the peripheral area PA, a driver, etc. for providing electrical signals or power to a pixel circuit corresponding to each of the pixels PX may be arranged. In the peripheral area PA, a pad, which is an area to which an electronic element, a printed circuit board, etc. may be electrically connected, may be arranged.

Hereinbelow, it is described that the display device 2 includes an organic light-emitting diode OLED as a light-emitting element. However, the display device 2 of one or more embodiments is not limited thereto. In one or more other embodiments, the display device 2 may be a light-emitting display device including an inorganic light-emitting diode, that is, an inorganic light-emitting display. The inorganic light-emitting diode may include a PN junction diode including materials based on an inorganic material semiconductor. When a voltage is applied to a PN junction diode in a forward direction, holes and electrons are injected, and energy generated by recombination of the holes and the electrons is converted to light energy to emit light of a corresponding color. The inorganic light-emitting diode described above may have a width of several to hundreds of micrometers, and in some embodiments, the inorganic light-emitting diode may be referred to as a micro light-emitting diode (LED). In one or more other embodiments, the display device 2 may be a quantum dot light-emitting display.

Meanwhile, the display device 2 may be used not only as portable electronic devices, such as mobile phones, smartphones, tablet personal computers (PCs), mobile communication terminals, electronic notebooks, electronic books, portable multimedia players (PMPs), navigations, and ultra mobile PCs (UMPC), but also as display screens of various products, such as televisions, laptops, monitors, billboards, and Internet of Things (IoT) devices. In addition, the display device 2 according to one or more embodiments may be used for wearable devices, such as smart watches, watch phones, glasses-type displays, and head-mounted displays (HMDs). In addition, the display device 2 according to one or more embodiments may be used for instrument panels of vehicles, center information displays arranged on center fascias or dashboards, room mirror displays replacing side-view mirrors of vehicles, or display screens arranged on a rear surface of a front seat as an entertainment for backseats of vehicles.

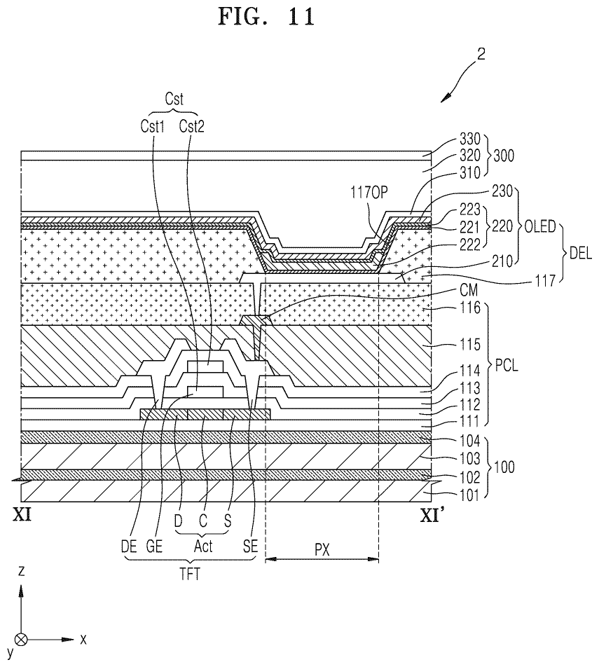

FIG. 11 is a cross-sectional view schematically illustrating a cross-section taken along the line XI-XI′ in FIG. 10.

Referring to FIG. 11, the display device 2 may include a stack structure of a substrate 100, a pixel circuit layer PCL, a display element layer DEL, and an encapsulation layer 300. The display substrate DP (see FIG. 1) may be during a manufacturing process for the display device 2, and for example, the display substrate DP may include the substrate 100, and may include, on the substrate 100, a stack structure of at least any of at least one layer of the pixel circuit layer PCL, at least one layer of the display element layer DEL, and at least one layer of the encapsulation layer 300.

The substrate 100 may have a multi-layer structure including a base layer including polymer resin and an inorganic layer. For example, the substrate 100 may include a base layer including polymer resin and a barrier layer that is an inorganic insulating layer. For example, the substrate 100 may include a first base layer 101, a first barrier layer 102, a second base layer 103, and a second barrier layer 104, which are sequentially stacked. The first base layer 101 and the second base layer 103 may include polyimide (PI), polyethersulfone (PES), polyarylate, polyetherimide (PEI), polyethylene naphthalate (PEN), polyethylene terephthalate (PET), polyphenylene sulfide (PPS), polycarbonate (PC), cellulose triacetate (TAC), and/or cellulose acetate propionate (CAP). The first barrier layer 102 and the second barrier layer 104 may include an inorganic insulating material, such as silicon oxide, silicon oxynitride, and/or silicon nitride. The substrate 100 may have flexible properties.

The pixel circuit layer PCL may be located on the substrate 100. FIG. 11 shows that the pixel circuit layer PCL includes a thin-film transistor TFT, and a buffer layer 111, a first gate-insulating layer 112, a second gate-insulating layer 113, an interlayer insulating layer 114, a first planarization insulating layer 115, and a second planarization insulating layer 116 that are located under and/or over the thin-film transistor TFT/parts of the thin-film transistor TFT.

The buffer layer 111 may reduce or block permeation of foreign substances, moisture, or outside air from a lower portion of the substrate 100, and may provide a flat surface on the substrate 100. The buffer layer 111 may include an inorganic insulating material, such as silicon oxide, silicon oxynitride, and silicon nitride, and may include a single-layer or multi-layer structure including the materials described above.

The thin-film transistor TFT, which is on the buffer layer 111, may include a semiconductor layer Act, and the semiconductor layer Act may include polysilicon. Alternatively, the semiconductor layer Act may include amorphous silicon, an oxide semiconductor, an organic semiconductor, etc. The semiconductor layer Act may include a channel region C, and a drain region D and a source region S that are arranged at opposite sides of the channel region C. A gate electrode GE may overlap the channel region C.

The gate electrode GE may include a low-resistance metal material. The gate electrode GE may include a conductive material, including molybdenum (Mo), aluminum (AI), copper (Cu), titanium (Ti), etc., and may include one or more layers including the materials described above.

The first gate-insulating layer 112, which is between the semiconductor layer Act and the gate electrode GE, may include an inorganic insulating material, such as silicon oxide (SiO₂), silicon nitride (SiNₓ), silicon oxynitride (SiOxNy), aluminum oxide (Al₂O₃), titanium oxide (TiO₂), tantalum oxide (Ta₂O₅), hafnium oxide (HfO₂), or zinc oxide (ZnOₓ). Zinc oxide (ZnOₓ) may be zinc oxide (ZnO) and/or zinc peroxide (ZnO₂).

The second gate-insulating layer 113 may be provided to cover the gate electrode GE. Similar to the first gate-insulating layer 112, the second gate-insulating layer 113 may include an inorganic insulating material, such as SiO₂, SiNₓ, SiOₓN_{y}, Al₂O₃, TiO₂, Ta₂O₅, HfO₂, or ZnOₓ. ZnOₓ may be ZnO and/or ZnO₂.

An upper electrode Cst2 of a storage capacitor Cst may be located over the second gate-insulating layer 113. The upper electrode Cst2 may overlap the gate electrode GE thereunder. In this case, the gate electrode GE and the upper electrode Cst2 overlapping each other with the second gate-insulating layer 113 therebetween may form the storage capacitor Cst. In other words, the gate electrode GE may function as a lower electrode Cst1 of the storage capacitor Cst.

As described above, the storage capacitor Cst and the thin-film transistor TFT may overlap each other. In some embodiments, the storage capacitor Cst may be formed so as not to overlap the thin-film transistor TFT.

The upper electrode Cst2 may include Al, platinum (Pt), palladium (Pd), silver (Ag), magnesium (Mg), gold (Au), nickel (Ni), neodymium (Nd), iridium (Ir), chrome (Cr), calcium (Ca), Mo, Ti, tungsten (W), and/or Cu, and may include one or more layers of the materials described above.

The interlayer insulating layer 114 may cover the upper electrode Cst2. The interlayer insulating layer 114 may include inorganic insulating materials such as SiO₂, SiNₓ, SiOₓN_{y}, Al₂O₃, TiO₂, Ta₂O₅, HfO₂, or ZnOₓ. ZnOₓ may be ZnO and/or ZnO₂. The interlayer insulating layer 114 may include one or more layers including the inorganic insulating materials described above.

A drain electrode DE and a source electrode SE may be positioned on the interlayer insulating layer 114. The drain electrode DE and the source electrode SE may be respectively connected to the drain region D and the source region S through contact holes formed in insulating layers thereunder. The drain electrode DE and the source electrode SE may include a material with good conductivity. The drain electrode DE and the source electrode SE may include a conductive material, including Mo, Al, Cu, Ti, etc., and may include one or more layers including the materials described above. In one or more embodiments, the drain electrode DE and the source electrode SE may have a multi-layer structure of Ti/AI/Ti.

The first planarization insulating layer 115 may cover the drain electrode DE and the source electrode SE. The first planarization insulating layer 115 may include an organic insulating material, such as general-purpose polymers, such as polystyrene (PS), polymethylmethacrylate (PMMA), polymer derivatives having a phenol-based group, acrylic-based polymers, imide-based polymers, aryl ether-based polymers, amide-based polymers, fluorine-based polymers, p-xylene-based polymers, vinyl alcohol-based polymers, and/or a blend thereof.

The second planarization insulating layer 116 may be located on the first planarization insulating layer 115. The second planarization insulating layer 116 may include a same material as the first planarization insulating layer 115, and may include an organic insulating material, such as general-purpose polymers, such as PS, PMMA, polymer derivatives having a phenol-based group, acrylic-based polymers, imide-based polymers, aryl ether-based polymers, amide-based polymers, fluorine-based polymers, p-xylene-based polymers, vinyl alcohol-based polymers, and/or a blend thereof.

The display element layer DEL may be located on the pixel circuit layer PCL with the structure described above. The display element layer DEL may include an organic light-emitting diode OLED as a display element (e.g., a light-emitting element), and the organic light-emitting diode OLED may include a stack structure of a pixel electrode 210, an intermediate layer 220, and a common electrode 230. For example, the organic light-emitting diode OLED may emit one of red, green, and blue light, or may emit one of red, green, blue, and white light. The organic light-emitting diode OLED may emit light through an emission area and define the emission area as a pixel PX.

The pixel electrode 210 of the organic light-emitting diode OLED may be electrically connected to the thin-film transistor TFT through contact holes formed in the second planarization insulating layer 116 and the first planarization insulating layer 115, and through a contact metal CM located on the first planarization insulating layer 115.

The pixel electrode 210 may include a conductive oxide, such as indium tin oxide (ITO), indium zinc oxide (IZO), zinc oxide (ZnO), indium oxide (In₂O₃), indium gallium oxide (IGO), or aluminum zinc oxide (AZO). In one or more other embodiments, the pixel electrode 210 may include a reflective film including Ag, Mg, Al, Pt, Pd, Au, Ni, Nd, Ir, Cr, or a compound thereof. In one or more other embodiments, the pixel electrode 210 may further include a film including ITO, IZO, ZnO, or In₂O₃, over/under the reflective film described above.

A pixel-defining layer 117 having an opening 117OP that exposes a central portion of the pixel electrode 210 may be located on the pixel electrode 210. The pixel-defining layer 117 may include an organic insulating material and/or an inorganic insulating material. The opening 1170P may define an emission area of light emitted from the organic light-emitting diode OLED. For example, a size/width of the opening 1170P may correspond to a size/width of the emission area. Accordingly a size and/or width of the pixel PX may depend on a size and/or width of the opening 1170P of the corresponding pixel-defining layer 117.

The intermediate layer 220 may include an emission layer 222 that is formed to correspond to the pixel electrode 210. The emission layer 222 may include a high-molecular weight organic material or low-molecular weight organic material that emits light of a corresponding color. Alternatively, the emission layer 222 may include an inorganic emission material or quantum dots.

In one or more embodiments, the intermediate layer 220 may include a first functional layer 221 and a second functional layer 223 that are respectively located under and over the emission layer 222. For example, the first functional layer 221 may include a hole transport layer, or may include a hole transport layer and a hole injection layer. The second functional layer 223 is an element located over the emission layer 222, and may include an electron transport layer and/or an electron injection layer. Similar to the common electrode 230 described below, the first functional layer 221 and/or the second functional layer 223 may be common layers formed to entirely cover the substrate 100. In this case, the first layer described with reference to FIGS. 1 to 3 may be a hole transport layer, the second layer may be a hole injection layer, and the third layer may be the emission layer 222. In addition, the fourth layer may be an electron transport layer, the fifth layer may be an electron injection layer, and the sixth-1 layer may be a common electrode. In this case, when a thickness of one layer of one intermediate layer 220 is different from a corresponding (e.g., preset) thickness, a thickness of the corresponding layer may be adjusted, or a thickness of another layer of the one intermediate layer 220 may be adjusted. For example, when a thickness of a hole transport layer is less than a corresponding (e.g., preset) thickness, the thickness of the hole transport layer may be adjusted, or a thickness of another layer excluding the hole transport layer may be adjusted. For example, a corresponding display substrate may be sent to the first processing portion again to deposit more hole transport layers on the display substrate, or alternatively, when forming a hole transport layer on a new display substrate, more hole transport layers may be deposited than before. Alternatively, when a thickness of another layer is adjusted, as described above with reference to FIGS. 1 to 3, a thickness of another layer in which optical characteristics that vary depending on a thickness is similar to those of a hole transport layer may be adjusted. In this case, according to a sum of a thickness of a hole transport layer and a thickness of another layer, the thickness of another layer may be adjusted so that final optical characteristics of the intermediate layer 220 correspond to corresponding (e.g., preset) optical characteristics.

In one or more other embodiments, when the thickness of the hole transport layer is greater than a corresponding (e.g., preset) thickness, the thickness of the hole transport layer may be adjusted, or a thickness of another layer different from the hole transport layer may be adjusted. When the thickness of the hole transport layer is adjusted, a thickness of a hole transport layer to be formed on a new display substrate may be adjusted. In addition, when a thickness of another layer different from the hole transport layer is adjusted, as described above with reference to FIGS. 1 to 3, a thickness of another layer in which optical characteristics that vary depending on a thickness is similar to those of a hole transport layer may be adjusted. In this case, according to a sum of a thickness of a hole transport layer and a thickness of another layer, the thickness of another layer may be adjusted so that final optical characteristics of the intermediate layer 220 correspond to corresponding (e.g., preset) optical characteristics.

The common electrode 230 may be located on the pixel electrode 210, and may overlap the pixel electrode 210. The common electrode 230 may include a conductive material having a low work function. For example, the common electrode 230 may include a (semi-)transparent layer including Ag, Mg, Al, Pt, Pd, Au, Ni, Nd, Ir, Cr, lithium (Li), Ca, or an alloy thereof. Alternatively, the common electrode 230 may further include a layer including ITO, IZO, ZnO, or In₂O₃, on the (semi-)transparent layer including the material described above. The common electrode 230 may be integrally formed to entirely cover the substrate 100.

The encapsulation layer 300 may be located on the display element layer DEL, and may cover the display element layer DEL. The encapsulation layer 300 may include at least one inorganic encapsulation layer and at least one organic encapsulation layer, and in one or more embodiments, FIG. 11 shows that the encapsulation layer 300 includes a first inorganic encapsulation layer 310, an organic encapsulation layer 320, and a second inorganic encapsulation layer 330 that are sequentially stacked.

The first inorganic encapsulation layer 310 and the second inorganic encapsulation layer 330 may include one or more inorganic materials from among aluminum oxide, titanium oxide, tantalum oxide, hafnium oxide, zinc oxide, silicon oxide, silicon nitride, or silicon oxynitride. Zinc oxide (ZnOₓ) may be zinc oxide (ZnO) and/or zinc peroxide (ZnO₂). The organic encapsulation layer 320 may include a polymer-based material. The polymer-based material may include acrylic-based resin, epoxy-based resin, PI, and polyethylene. In one or more embodiments, the organic encapsulation layer 320 may include acrylate. The organic encapsulation layer 320 may be formed by curing a monomer or applying a polymer. The organic encapsulation layer 320 may be transparent.

In one or more embodiments, a touch sensor layer may be located on the encapsulation layer 300, and an optical functional layer may be located on the touch sensor layer. The touch sensor layer may obtain coordinate information according to an external input, for example, a touch event. The optical functional layer may reduce reflectivity of light (external light) incident toward the display device from the outside and/or improve color purity of light emitted from the display device. In one or more embodiments, the optical functional layer may include a phase retarder and/or a polarizer. The phase retarder may be of a film-type or a liquid crystal coating type, and may include a λ/2 phase retarder and/or a λ/4 phase retarder. The polarizer may also be of a film type or a liquid crystal coating type. The film-type polarizer may include a stretchable synthetic resin film, and the liquid crystal coating-type polarizer may include liquid crystals arranged in a corresponding arrangement. The phase retarder and the polarizer may further include a protective film.

An adhesive member may be arranged between the touch sensor layer and the optical functional layer. The adhesive member may be any general material known in the art without limitation. The adhesive member may be a pressure sensitive adhesive (PSA) member.

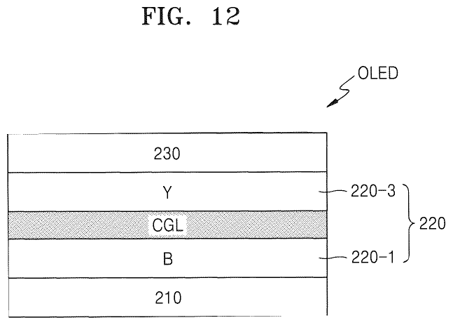

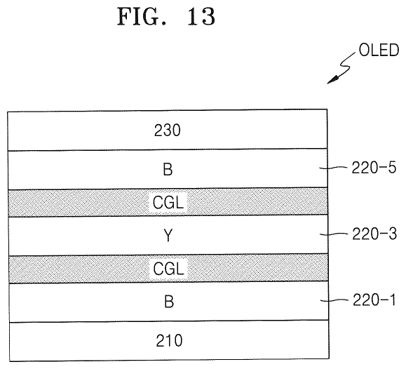

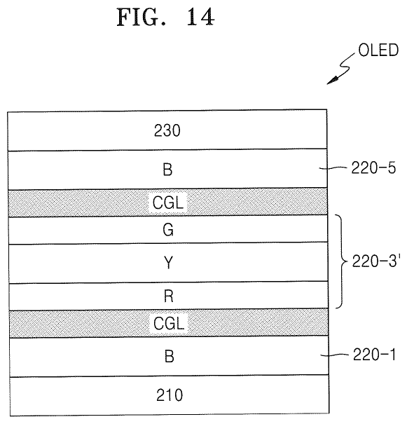

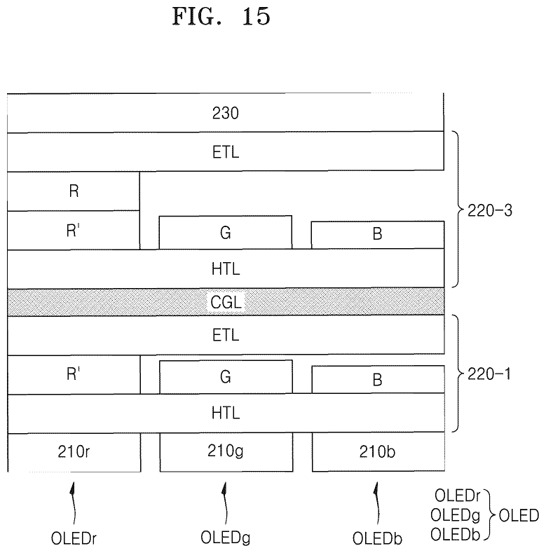

FIG. 12 is a cross-sectional view schematically illustrating the organic light-emitting diode OLED of the display device 2 in FIG. 11. FIG. 13 is a cross-sectional view schematically illustrating the organic light-emitting diode OLED of the display device 2 in FIG. 11. FIG. 14 is a cross-sectional view schematically illustrating the organic light-emitting diode OLED of the display device 2 in FIG. 11. FIG. 15 is a cross-sectional view schematically illustrating the organic light-emitting diode OLED of the display device 2 in FIG. 11.

Referring to FIGS. 12 to 15, the organic light-emitting diode OLED may include a single emission layer. However, one or more embodiments are not limited thereto. As in FIGS. 12 to 15, the organic light-emitting diode OLED may have a tandem structure in which a plurality of emission layers are stacked.

Referring to FIG. 12, the organic light-emitting diode OLED may include the pixel electrode 210, which is an anode electrode, the common electrode 230, which is a cathode electrode, and a first emission unit 220-1 and a second emission unit 220-3 as a stacked intermediate layer between the pixel electrode 210 and the common electrode 230. A charge generation layer CGL may be arranged between the first emission unit 220-1 and the second emission unit 220-3 of the organic light-emitting diode OLED.

The first emission unit 220-1 may include a blue emission layer B. A hole injection layer and/or a hole transport layer may be arranged between the pixel electrode 210 and the blue emission layer B. An electron injection layer and/or an electron transport layer may be arranged between the blue emission layer B and the charge generation layer CGL.

The second emission unit 220-3 may include a yellow emission layer Y. A hole injection layer and/or a hole transport layer may be arranged between the charge generation layer CGL and the yellow emission layer Y. An electron injection layer and/or an electron transport layer may be arranged between the yellow emission layer Y and the common electrode 230.

The charge generation layer CGL may be arranged between the first emission unit 220-1 and the second emission unit 220-3, so that a charge between the first emission unit 220-1 and the second emission unit 220-3 is adjusted to achieve charge balance.

The charge generation layer CGL may be provided by stacking an n-type layer positioned adjacent to the first emission unit 220-1 to supply electrons to the first emission unit 220-1, and a p-type layer positioned adjacent to the second emission unit 220-3 to supply holes to the second emission unit 220-3.

Referring to FIG. 13, the organic light-emitting diode OLED may include the pixel electrode 210, which is an anode electrode, the common electrode 230, which is a cathode electrode, and the first emission unit 220-1, the second emission unit 220-3, and a third emission unit 220-5 that are stacked between the pixel electrode 210 and the common electrode 230. The charge generation layer CGL may be arranged between the first emission unit 220-1 and the second emission unit 220-3 of the organic light-emitting diode OLED, and between the second emission unit 220-3 and the third emission unit 220-5 of the organic light-emitting diode OLED.

The first emission unit 220-1 may include the blue emission layer B. A hole injection layer and/or a hole transport layer may be located under the blue emission layer B, and an electron injection layer and/or an electron transport layer may be located over the blue emission layer B. The blue emission layer B may be arranged between the A hole injection layer and/or a hole transport layer and an electron injection layer and/or an electron transport layer.

The second emission unit 220-3 may include the yellow emission layer Y. A hole injection layer and/or a hole transport layer may be located under the yellow emission layer Y, and an electron injection layer and/or an electron transport layer may be located over the yellow emission layer Y. The yellow emission layer Y may be arranged between the A hole injection layer and/or a hole transport layer and an electron injection layer and/or an electron transport layer.

The third emission unit 220-5 may include the blue emission layer B. A hole injection layer and/or a hole transport layer may be located under the blue emission layer B, and an electron injection layer and/or an electron transport layer may be located over the blue emission layer B. The blue emission layer B may be arranged between the A hole injection layer and/or a hole transport layer and an electron injection layer and/or an electron transport layer.

The charge generation layer(s) CGL may be arranged (e.g., respectively) between the first, second, and third emission units 220-1, 220-3, and 220-5, and may be provided by stacking an n-type layer that supplies electrons and a p-type layer that supplies holes.

Referring to FIG. 14, the organic light-emitting diode OLED may include the pixel electrode 210, which is an anode electrode, the common electrode 230, which is a cathode electrode, and the first emission unit 220-1, the second emission unit 220-3′, and the third emission unit 220-5 that are stacked between the pixel electrode 210 and the common electrode 230. The charge generation layer CGL may be arranged between the first emission unit 220-1 and the second emission unit 220-3′ of the organic light-emitting diode OLED, and between the second emission unit 220-3′ and the third emission unit 220-5 of the organic light-emitting diode OLED.

The one or more embodiments corresponding to FIG. 14 is a modification of the second emission unit 220-3′ in the one or more embodiments corresponding to FIG. 13. A second emission unit 220-3′ may further include a red emission layer R and/or a green emission layer G in addition to the yellow emission layer Y.

In FIG. 14, the red emission layer R is located under the yellow emission layer Y, and the green emission layer G is located over the yellow emission layer Y. However, one or more embodiments are not limited thereto.

For example, the red emission layer R is located on both an upper portion and a lower portion of the yellow emission layer Y, or the green emission layer G may be located on both the upper portion and the lower portion of the yellow emission layer Y. Alternatively, the red emission layer R or the green emission layer G may be located only on one of the upper portion or the lower portion of the yellow emission layer Y, and various modifications may be made.

The organic light-emitting diode OLED in FIGS. 12 to 14 may be formed integrally with a plurality of pixels arranged in the display area DA. In this case, the organic light-emitting diode OLED may emit white or blue light. A color filter may be located on the organic light-emitting diode OLED and may implement a color according to each pixel.

Referring to FIG. 15, the organic light-emitting diode OLED may include a red organic light-emitting diode OLEDr, a green organic light-emitting diode OLEDg, and a blue organic light-emitting diode OLEDb that emit light of different colors from each other.

The red organic light-emitting diode OLEDr, the green organic light-emitting diode OLEDg, and the blue organic light-emitting diode OLEDb may all have a tandem structure.

The red organic light-emitting diode OLEDr may be provided by sequentially stacking a first pixel electrode 210r, the first emission unit 220-1 including the red emission layer R′, the charge generation layer CGL, the second emission unit 220-3 including the red emission layer R and an additional red emission layer R′, and the common electrode 230. The first emission unit 220-1 and the second emission unit 220-3 may each include a hole injection layer HTL located under the additional red emission layer R′, and an electron injection layer ETL located over the red emission layer R′.

The green organic light-emitting diode OLEDg may be provided by sequentially stacking a second pixel electrode 210g, the first emission unit 220-1 including the green emission layer G, the charge generation layer CGL, the second emission unit 220-3 including the green emission layer G, and the common electrode 230. The first emission unit 220-1 and the second emission unit 220-3 may each include the hole injection layer HTL located under the green emission layer G and the electron injection layer ETL located over the green emission layer G.

The blue organic light-emitting diode OLEDb may be provided by sequentially stacking a third pixel electrode 210b, the first emission unit 220-1 including the blue emission layer B, the charge generation layer CGL, the second emission unit 220-3 including the blue emission layer B, and the common electrode 230. The first emission unit 220-1 and the second emission unit 220-3 may respectively include the hole injection layer HTL located under the blue emission layer B and the electron injection layer ETL located over the blue emission layer B.

The hole injection layer HTL, the electron injection layer ETL, and the charge generation layer CGL may be integrally formed across the red organic light-emitting diode OLEDr, the green organic light-emitting diode OLEDg, and the blue organic light-emitting diode OLEDb. In some embodiments, to improve leakage current due to the charge generation layer CGL, a separator may be arranged between the organic light-emitting diodes OLED.

Thicknesses of the red emission layer R, the green emission layer G, and the blue emission layer B respectively included in the red organic light-emitting diode OLEDr, the green organic light-emitting diode OLEDg, and the blue organic light-emitting diode OLEDb may be different from each other. These may be set in consideration of a thickness at which light resonates according to a wavelength emitted from an emission layer. For example, a thickness of the red emission layer R may be greater than a thickness of the green emission layer G. A thickness of the green emission layer G may be greater than a thickness of the blue emission layer B.

When the organic light-emitting diode OLED has a tandem structure, the organic light-emitting diode OLED may have high brightness and long lifespan.

As described above, when the organic light-emitting diode OLED has a tandem structure, there may be cases in which at least two layers have a same material. In this case, the at least two layers having the same material may be performed in a same processing portion. In this case, the display substrate may move in one direction according to formation of each layer and then return in an opposite direction to perform each process. In one or more other embodiments, different clusters may be provided as many as a number of layers of the organic light-emitting diode OLED, or each layer may be formed in each cluster.

In this case, when a thickness of one layer from among at least two layers is different from a corresponding (e.g., preset) thickness, a thickness of the other layer from among the at least two layers may be adjusted. For example, when the thickness of one layer from among the at least two layers is less than the corresponding (e.g., preset) thickness, the thickness of the other layer from among the at least two layers may be adjusted to be greater than the corresponding (e.g., preset) thickness. In addition, when the thickness of one layer from among the at least two layers is greater than the corresponding (e.g., preset) thickness, the thickness of the other layer from among the at least two layers may be adjusted to be less than the corresponding (e.g., preset) thickness.

In addition to the above, when a thickness of one layer of the organic light-emitting diode OLED is different from a corresponding (e.g., preset) thickness so that optical characteristics of the organic light-emitting diode OLED correspond to corresponding (e.g., preset) optical characteristics, a thickness of another layer of the organic light-emitting diode OLED may be adjusted.

Thus, in the apparatus and method for manufacturing a display device, a display device that implements a clear image may be manufactured.

In the apparatus and method for manufacturing a display device, according to one or more embodiments, a thickness of a layer may be adjusted in real time by measuring the thickness of the layer.

In the apparatus and method for manufacturing a display device, according to one or more embodiments, a high-resolution display device may be manufactured.

In the apparatus and method for manufacturing a display device, according to one or more embodiments, a thickness of a layer may be measured at an accurate position.

In the apparatus and method for manufacturing a display device, according to one or more embodiments, measurement errors due to bending of a substrate may be reduced.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope as defined by the following claims.

What is claimed is:

1. An apparatus for manufacturing a display device, the apparatus comprising:
a seating portion on which a substrate having a dummy layer thereon is seated;
support portions on the seating portion to support the substrate;
a measurement portion facing the seating portion, and configured to measure a thickness of the dummy layer,
wherein the seating portion is configured to move linearly so that the measurement portion and the dummy layer are positioned at corresponding positions based on a result of detection by the measurement portion.

2. The apparatus of claim 1, further comprising a driving portion connected to the seating portion, and configured to move the seating portion linearly.

3. The apparatus of claim 1, further comprising a detection portion configured to detect a position of the seating portion and a position of the substrate.

4. The apparatus of claim 3, wherein the seating portion is further configured to move the substrate linearly based on a result of detection by the detection portion.

5. The apparatus of claim 1, wherein the support portions are at different respective heights.

6. The apparatus of claim 1, further comprising a movement driving portion configured to move a detection portion or the measurement portion therein.

7. The apparatus of claim 1, further comprising:
a processing portion configured to deposit a layer on the substrate; and
a path unit connected to the processing portion, and configured to determine a movement path of the substrate,
wherein the seating portion, the support portions, and the measurement portion are arranged in the processing portion or in the path unit.

8. The apparatus of claim 7, wherein the processing portion comprises a first processing portion and a second processing portion configured to deposit respective layers on the substrate, and
wherein a thickness of a layer on the substrate is configured to be adjusted in the first processing portion or in the second processing portion based on a measurement of the layer on the substrate in the first processing portion.

9. The apparatus of claim 1, further comprising a substrate pressing portion facing the support portions or the seating portion, and configured to keep at least a portion of the substrate flat.

10. The apparatus of claim 1, wherein the measurement portion is further configured to irradiate a signal in a direction perpendicular to one surface of the dummy layer.

11. A method of manufacturing a display device, the method comprising:
moving a substrate on a seating portion to a position;
separating the substrate from a support portion;
moving the support portion to an initial position;
seating the substrate on the support portion;
moving the substrate to the position; and
moving the support portion so that a dummy layer on the substrate corresponds to a dummy position.

12. The method of claim 11, further comprising detecting the position of the substrate and a position of the seating portion.

13. The method of claim 11, further comprising measuring a thickness of the dummy layer.

14. The method of claim 13, wherein the thickness of the dummy layer is measured during transferring of the substrate.

15. The method of claim 13, wherein the thickness of the dummy layer is measured at a space of the substrate having a same layer as the dummy layer.

16. The method of claim 11, further comprising measuring a position of the dummy layer.

17. The method of claim 16, further comprising comparing the position of the dummy layer with the dummy position.

18. The method of claim 11, further comprising supporting different portions of the substrate at different respective heights.

19. The method of claim 11, further comprising keeping the substrate flat.

20. The method of claim 11, further comprising keeping a portion of the substrate flat by applying a pressure to an end of the substrate adjacent to the dummy layer, the dummy layer being at the portion of the substrate.
